(19) United States
(12) Patent Application Publication
(10) Pub. No.: US 2019/0064663 A1
(43) Pub. Date: Feb. 28, 2019

(54) RESIST COMPOSITION AND METHOD OF FORMING RESIST PATTERN

(71) Applicant: TOKYO OHKA KOGYO CO., LTD., Kawasaki-shi (JP)

(72) Inventors: Tsuyoshi NAKAMURA, Yeonsu-Gu, Incheon (KR); Kazuishi TANNO, Yeonsu-Gu, Incheon (KR); JunYeob LEE, Yeonsu-Gu, Incheon (KR)

(21) Appl. No.: 16/086,755

(22) PCT Filed: Mar. 23, 2017
(86) PCT No.: PCT/JP2017/011756

§ 371 Date: Sep. 20, 2018

(30) Foreign Application Priority Data
Mar. 31, 2016 (KR) 10-2016-0039697

(51) Int. Cl. G03F 7/039; G03F 7/038; G03F 7/004

(52) U.S. Cl. CPC G03F 7/0397; G03F 7/32; G03F 7/0045; G03F 7/0382

(57) ABSTRACT

A resist composition including a base component which exhibits changed solubility in a developing solution under action of acid and an acid-generator component which generates acid upon exposure, the base component containing a polymer having a structural unit represented by formula (1), and the acid-generator component having an anion represented by formula (2) (in formula (1), Rₓ represents a hydrogen atom, an alkyl group having 1 to 5 carbon atoms or a halogenated alkyl group having 1 to 5 carbon atoms; Z represents a single bond or an alkyl group having 1 to 5 carbon atoms; Cₚ is a group represented by formula (Cp-1); in formula (Cp-1), R₂ represents a tertiary alkyl group; in formula (2), R_{y} represents a cyclic hydrocarbon group of 3 to 20 carbon atoms which may have a hetero atom; A represents —O(C═O)— or —(C═)O—; L represents a single bond or a divalent hydrocarbon group containing a hetero atom; each X independently represents H or F; and n represents an integer of 0 to 10).

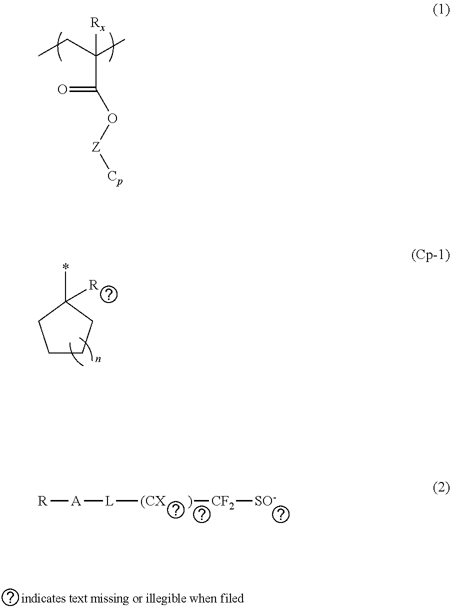

### TECHNICAL FIELD

The present invention relates to a resist composition and a method of forming a resist pattern.

Priority is claimed on Korean Patent Application No. 2016-0039697, filed Mar. 31, 2016, the content of which is incorporated herein by reference.

### DESCRIPTION OF RELATED ART

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film.

A resist material in which the exposed portions become soluble in a developing solution is called a positive-type, and a resist material in which the exposed portions become insoluble in a developing solution is called a negative-type.

In recent years, in the production of semiconductor elements and liquid crystal display elements, advances in lithography techniques have led to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production. Furthermore, research is also being conducted into lithography techniques that use an exposure light source having a wavelength shorter (energy higher) than these excimer lasers, such as electron beam, extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified composition is used, which includes a base material component that exhibits a changed solubility in a developing solution under the action of acid and an acid-generator component that generates acid upon exposure.

For example, in the case where the developing solution is an alkali developing solution (alkali developing process), the positive chemically amplified resist composition typically contains a resin component (base component) which exhibits increased alkali solubility in an alkali developing solution under action of acid, and an acid-generator component.

If a resist film formed using such a resist composition is selectively exposed at the time of forming a resist pattern, in exposed areas, acid is generated from the acid generator component, and the polarity of the base resin increases by the action of the generated acid, thereby making the exposed areas soluble in the alkali developing solution. Thus, by conducting alkali developing, the unexposed portions remain to form a positive resist pattern.

On the other hand, when such a base resin is applied to a solvent developing process using a developing solution containing an organic solvent (organic developing solution), the solubility of the exposed portions in an organic developing solution is decreased. As a result, the unexposed portions of the resist film are dissolved and removed by the organic developing solution, and a negative resist pattern in which the exposed portions are remaining is formed. Such a solvent developing process for forming a negative-tone resist composition is sometimes referred to as “negative-tone developing process” (for example, see Patent Literature 1).

For example, in the case of a resin composition which exhibits increased solubility in an alkali developing solution by the action of acid, a structural unit containing an acid decomposable group which is decomposed by the action of acid generated from an acid generator component and exhibits increased polarity. Further, a structural unit containing a lactone-containing cyclic group or a structural unit containing a polar group such as a hydroxy group is used in combination (for example, see Patent Literature 2).

Recently, as miniaturization of pattern progresses, demands for a polymeric compound useful as a base resin for a resist composition has been increasing.

For example, there has been proposed a polymeric compound using a polycyclic ester containing an electron-withdrawing substituent and a lactone skeleton as a monomer, and a resist composition containing the polymeric compound (see Patent Literature 3)

### DOCUMENTS OF RELATED ART

### Patent Literature

[Patent Literature 1] Japanese Unexamined Patent Application, First Publication No. 2009-025723

[Patent Document 2] Japanese Unexamined Patent Application, First Publication No. 2003-241385

[Patent Document 3] Japanese Unexamined Patent Application, First Publication No. 2008-231059

### SUMMARY OF THE INVENTION

### Problems to be Solved by the Invention

As further progress is made in lithography techniques and the application field for lithography techniques expand, in the formation of a resist pattern, further improvement in various lithography properties such as sensitivity improvement, resolution and improvement in roughness is demanded.

However, among the above lithography properties, for improving CDU (Critical Dimension Uniformity) and LWR (Line Width Roughness), it is important to control diffusion of acid. There was a problem in that, when the diffusion becomes short, the sensitivity tends to be deteriorated.

The present invention takes the above circumstances into consideration, with an object of providing a resist composition capable of forming a resist pattern with improved CDU and LWR, and a method of forming a resist pattern using the resist composition.

Another object of the present invention is to provide a resist composition which may be used in either negative-tone development or positive-tone development without any problems.

### Means to Solve the Problems

As a result of the studies of the present inventors, they have found that the above problems may be solved when a resist composition contains a polymer having a specific structural unit, and also contains an acid-generator component having a specific anion. The present invention has been completed based on this finding.

Specifically, a first aspect of the present invention is a resist composition including a base component (A) which exhibits changed solubility in a developing solution under action of acid and an acid-generator component (B) which generates acid upon exposure,

the base component (A) containing a polymer having a structural unit represented by general formula (1) shown below, and

the acid-generator component (B) having an anion represented by general formula (2) shown below:

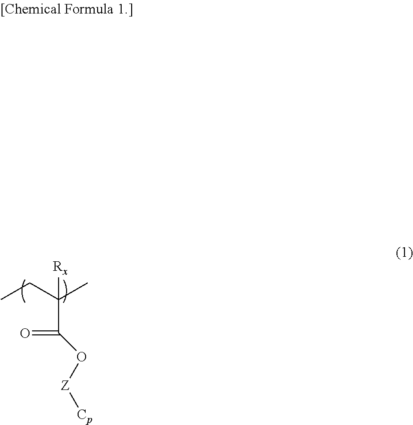

In general formula (1), Rₓ represents a hydrogen atom, an alkyl group having 1 to 5 carbon atoms or a halogenated alkyl group having 1 to 5 carbon atoms; Z represents a single bond or an alkyl group having 1 to 5 carbon atoms; Cₚ is a group represented by general formula (Cp-1) shown below:

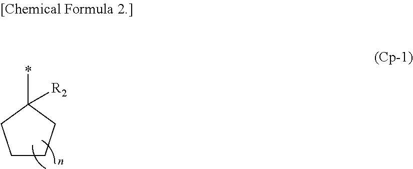

In the formula, R₂ represents a tertiary alkyl group; n represents a positive integer; and * indicates the bonding position with Z.

[Chemical Formula 3.]

R_{y}-A-L-(CX₂)ₙ—CF₂—SO₃⁻ (2)

In general formula (2), R_{y} represents a cyclic hydrocarbon group of 3 to 20 carbon atoms which may have a hetero atom; A represents —O (C═O)— or —(C═O)O—; L represents a single bond or a divalent hydrocarbon group containing a hetero atom, provided that a hydrogen atom of the divalent hydrocarbon group containing a hetero atom may be substituted with a substituent; each X independently represents H or F; and n represents an integer of 0 to 10.

A second aspect of the present invention is a method of forming a resist pattern, including: using a resist composition according to the first aspect to form a resist film on a substrate, exposing the resist film, and developing the exposed resist film to form a resist pattern.

### Effects of the Invention

According to the present invention, there are provided a resist composition capable of forming a resist pattern with improved CDU and LWR, and a method of forming a resist pattern using the resist composition.

### DETAILED DESCRIPTION OF THE INVENTION

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic, divalent saturated hydrocarbon, unless otherwise specified.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

A “fluorinated alkyl group” or a “fluorinated alkylene group” is a group in which part or all of the hydrogen atoms of an alkyl group or an alkylene group have been substituted with a fluorine atom.

The term “structural unit” refers to a monomer unit that contributes to the formation of a polymeric compound (resin, polymer, copolymer).

The expression “may have a substituent” means that a case where a hydrogen atom (—H) is substituted with a monovalent group, or a case where a methylene (—CH₂—) group is substituted with a divalent group.

The term “exposure” is used as a general concept that includes irradiation with any form of radiation.

A “structural unit derived from an acrylate ester” refers to a structural unit that is formed by the cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

The acrylate ester may have the hydrogen atom bonded to the carbon atom on the α-position substituted with a substituent. The substituent (R^{α0}) that substitutes the hydrogen atom bonded to the carbon atom on the α-position is an atom other than hydrogen or a group, and examples thereof include an alkyl group of 1 to 5 carbon atoms and a halogenated alkyl group of 1 to 5 carbon atoms. Further, an acrylate ester having the hydrogen atom bonded to the carbon atom on the α-position substituted with a substituent (R^{α0}) in which the substituent has been substituted with a substituent containing an ester bond (e.g., an itaconic acid diester), or an acrylic acid having the hydrogen atom bonded to the carbon atom on the α-position substituted with a substituent (R^{α0}) in which the substituent has been substituted with a hydroxyalkyl group or a group in which the hydroxy group within a hydroxyalkyl group has been modified (e.g., α-hydroxyalkyl acrylate ester) can be mentioned as an acrylate ester having the hydrogen atom bonded to the carbon atom on the α-position substituted with a substituent. A carbon atom on the α-position of an acrylate ester refers to the carbon atom bonded to the carbonyl group, unless specified otherwise.

Hereafter, an acrylate ester having the hydrogen atom bonded to the carbon atom on the α-position substituted with a substituent is sometimes referred to as “α-substituted acrylate ester”. Further, acrylate esters and α-substituted acrylate esters are collectively referred to as “(α-substituted) acrylate ester”.

<<Resist Composition>>

The resist composition according to a first aspect of the present invention is a resist composition which generates acid upon exposure and exhibits changed solubility in a developing solution under action of acid, the resist composition including a base component (A) which exhibits changed solubility in a developing solution under action of acid (hereafter, also referred to as “component (A)”), and an acid generator component (B) which generates acid upon exposure (hereafter, also referred to as “component (B)”).

When a resist film is formed using the resist composition and the formed resist film is subjected to a selective exposure, acid is generated at exposed portions, and the generated acid acts on the component (A) to change the solubility of the component (A) in a developing solution, whereas the solubility of the component (A) in a developing solution is not changed at unexposed portions, thereby generating difference in solubility in a developing solution between exposed portions and unexposed portions. Therefore, by subjecting the resist film to development, the exposed portions are dissolved and removed to form a positive-tone resist pattern in the case of a positive resist, whereas the unexposed portions are dissolved and removed to form a negative-tone resist pattern in the case of a negative resist.

In the present specification, a resist composition which forms a positive resist pattern by dissolving and removing the exposed portions is called a positive resist composition, and a resist composition which forms a negative resist pattern by dissolving and removing the unexposed portions is called a negative resist composition.

The resist composition of the present invention may be either a positive resist composition or a negative resist composition.

Further, in the formation of a resist pattern, the resist composition of the present invention can be applied to an alkali developing process using an alkali developing solution in the developing treatment, or a solvent developing process using a developing solution containing an organic solvent (organic developing solution) in the developing treatment.

Specifically, the resist composition according to the present embodiment contains an acid-generator component (B) which generates acid upon exposure, and this case, the component (A) is “the base component which exhibits changed solubility by in a developing solution by the action of acid”.

<Component (A)>

In the present invention, the term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed.

The organic compound used as the base component is broadly classified into non-polymers and polymers.

In general, as a non-polymer, any of those which have a molecular weight in the range of 500 to less than 4,000 is used. Hereafter, a “low molecular weight compound” refers to a non-polymer having a molecular weight in the range of 500 to less than 4,000.

As a polymer, any of those which have a molecular weight of 1,000 or more is generally used. Hereafter, a “resin” refers to a polymer having a molecular weight of 1,000 or more.

As the molecular weight of the polymer, the weight average molecular weight in terms of the polystyrene equivalent value determined by gel permeation chromatography (GPC) is used.

As the base component usable in the resist composition of the present invention, at least the component (A) is used, and another polymeric compound and/or a low molecular weight compound may be used in combination with the component (A).

The component (A) may be a resin that exhibits increased solubility in a developing solution under action of acid or a resin that exhibits decreased solubility in a developing solution under action of acid.

In the resist composition of the present invention, the component (A) contains a polymer having a structural unit represented by general formula (1) shown below.

In the case where a resist film is formed using a resist composition containing the component (A), at least a part of the structure in the structural unit is cleaved by the action of acid, and the polarity is increased. Therefore, the resist composition of the present embodiment becomes a negative-type in the case where the developing solution is an organic developing solution (solvent developing process), and a positive-type in the case where the developing solution is an alkali developing solution (alkali developing process). Since the polarity of the component (A) changes before and after exposure, by using the component (A), a fine development contrast can be obtained not only in an alkali developing process but also in a solvent developing process.

That is, in the case where a solvent developing process is applied, the component (A) exhibits high solubility in an organic developing solution prior to exposure. When acid is generated upon exposure, polarity is increased by the action of acid, and solubility in an organic developing solution is decreased. Therefore, in the formation of a resist pattern, by conducting selective exposure of a resist film formed by applying the resist composition to a substrate, the exposed portions of the resist film changes from an soluble state to a hardly-soluble state in an organic developing solution, whereas the unexposed portions of the resist film remain soluble in an organic developing solution. As a result, by conducting development using an organic developing solution, a contrast can be made between the exposed portions and unexposed portions, thereby forming a negative resist pattern.

On the other hand, in the case of applying an alkali developing process, the component (A) exhibits low solubility in an alkali developing solution prior to exposure. When acid is generated upon exposure, polarity is increased by the action of acid, and solubility in an alkali developing solution is increased. Therefore, in the formation of a resist pattern, by conducting selective exposure of a resist film formed by applying the resist composition to a substrate, the exposed portions of the resist film change from a hardly-soluble state to a soluble state in an alkali developing solution, whereas the unexposed portions of the resist film remain hardly-soluble in an alkali developing solution, and hence, a positive resist pattern is formed by alkali developing.

Polymer Having Structural Unit Represented by General Formula (1)

The structural unit represented by general formula (1) is shown as follows.

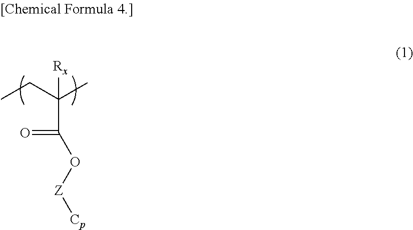

In general formula (1), Rₓ represents a hydrogen atom, an alkyl group having 1 to 5 carbon atoms or a halogenated alkyl group having 1 to 5 carbon atoms; Z represents a single bond or an alkyl group having 1 to 5 carbon atoms; Cₚ is a group represented by general formula (Cp-1) shown below:

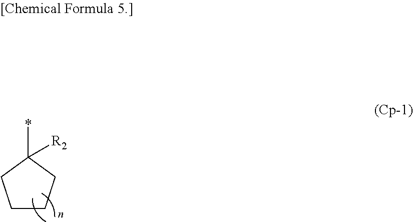

In the formula, R₂ represents a tertiary alkyl group; n represents a positive integer; and * indicates the bonding position with Z.

In general formula (1), Rₓ represents a hydrogen atom, an alkyl group of 1 to 5 carbon atoms or a halogenated alkyl group of 1 to 5 carbon atoms.

As the alkyl group of 1 to 5 carbon atoms for Rₓ, a linear or branched alkyl group of 1 to 5 carbon atoms is preferable, and specific examples thereof include a methyl group, an ethyl group, an n-propyl group, an isopropyl group, an n-butyl group, an isobutyl group, a tert-butyl group, a pentyl group, an isopentyl group and a neopentyl group.

The halogenated alkyl group of 1 to 5 carbon atoms represented by Rₓ is a group in which part or all of the hydrogen atoms of the aforementioned alkyl group of 1 to 5 carbon atoms have been substituted with halogen atoms. Examples of the halogen atom include a fluorine atom, a chlorine atom, a bromine atom and an iodine atom, and a fluorine atom is particularly desirable.

As Rₓ, an alkyl group of 1 to 5 carbon atoms or a fluorinated alkyl group of 1 to 5 carbon atoms is preferable, and in terms of industrial availability, a hydrogen atom or an alkyl group of 1 to 5 carbon atoms is more preferable, an alkyl group of 1 to 5 carbon atoms is still more preferable, and a methyl group is still most preferable.

In general formula (1), Z represents a single bond or an alkyl group of 1 to 5 carbon atoms.

As the alkyl group for Z, the alkyl group having 1 to 5 carbon atoms defined for Rₓ may be mentioned.

In general formula (1), Cₚ is a group represented by the aforementioned general formula (Cp-1).

In general formula (Cp-1), R2 represents a tertiary alkyl group, and the tertiary alkyl group preferably has 4 to 10 carbon atoms, more preferably 4 to 6 carbon atoms, and a tert-butyl group is most preferable.

In general formula (Cp-1), n represents a positive integer, preferably 1 to 10, more preferably 1 to 5, and most preferably 1 to 3.

The aforementioned structural unit is a structural unit containing an acid decomposable group that exhibits increased polarity by the action of acid.

The term “acid decomposable group” refers to a group in which at least a part of the bond within the structure thereof is cleaved by the action of an acid.

In the structural unit, the acid decomposable group requires relatively low activation energy as compared to other acid decomposable groups when at least a part of the bond in the structure of the acid decomposable group is cleaved by the action of acid (i.e., the acid decomposable group is more reliably dissociated by the action of acid).

The acid decomposable group in the structural unit is decomposed by the action of acid to generate a polar group (carboxy group). That is, the acid decomposable group may be referred to as a group in which the polar group is protected by an acid dissociable group having a specific monocyclic structure.

The amount of the structural unit of the polymer contained in the component (A), based on the combined total of all structural units is preferably 5 to 70 mol %, more preferably 10 to 60 mol %, and still more preferably 10 to 50 mol %.

In the present invention, preferable examples of the structural unit of the polymer contained in the component (A) are as follows.

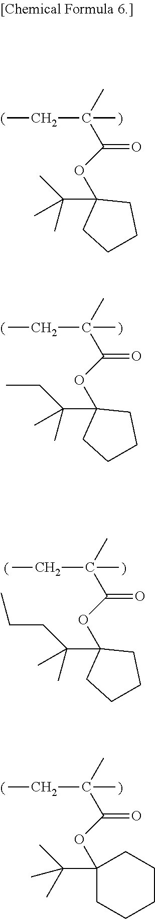

In the resist composition of the present embodiment, the amount of the component (A) may be appropriately adjusted depending on the thickness of the resist film to be formed, and the like.

<Component (B)>

In the present invention, the resist composition contains an acid-generator component (B) that generates acid upon exposure.

{Anion Moiety}

The component (B) includes an acid generator having an anion represented by formula (2) shown below.

[Chemical Formula 7.]

R_{y}-A-L-(CX₂)ₙ—CF₂—SO₃⁻ (2)

In the formula, R_{y} represents a cyclic hydrocarbon group of 3 to 20 carbon atoms which may have a hetero atom; A represents —O(C═O)— or —(C═)O—; L represents a single bond or a divalent hydrocarbon group containing a hetero atom, provided that a hydrogen atom of the divalent hydrocarbon group containing a hetero atom may be substituted with a substituent; each X independently represents H or F; and n represents an integer of 0 to 10.

Cyclic Hydrocarbon Group of 3 to 20 Carbon Atoms Represented by R_{y} which may have a Hetero Atom

The cyclic hydrocarbon group for R_{y} may be an aromatic hydrocarbon group or an aliphatic hydrocarbon group. An “aliphatic hydrocarbon group” refers to a hydrocarbon group that has no aromaticity. The aliphatic hydrocarbon group as the cyclic hydrocarbon group for R_{y} may be either saturated or unsaturated, and is preferably saturated.

Examples of the aliphatic cyclic group for R_{y} include an alicyclic hydrocarbon group (a group in which 1 hydrogen atom has been removed from an aliphatic hydrocarbon ring); a group in which an alicyclic hydrocarbon group is bonded to a terminal of a linear or branched aliphatic hydrocarbon group; and a group in which an alicyclic hydrocarbon group is present between carbon atoms of a linear or branched aliphatic hydrocarbon group.

The alicyclic hydrocarbon group may be either a polycyclic group or a monocyclic group. As the monocyclic aliphatic hydrocarbon group, a group in which 1 hydrogen atom has been removed from a monocycloalkane is preferable. The monocycloalkane preferably has 3 to 6 carbon atoms, and specific examples thereof include cyclopentane and cyclohexane.

As the polycyclic group, a group in which 1 hydrogen atom has been removed from a polycycloalkane is preferable, and the polycyclic group preferably has 7 to 12 carbon atoms. Examples of the polycycloalkane include adamantane, norbornane, isobornane, tricyclodecane and tetracyclododecane.

As the linear aliphatic hydrocarbon group, a linear alkyl group is preferable, and specific examples thereof include a methyl group, an ethyl group, a propyl group, a butyl group, and a pentyl group.

As the branched aliphatic hydrocarbon group, a branched alkyl group is preferable, and specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

As the cyclic aromatic hydrocarbon group for R_{y}, an aryl group such as a phenyl group or a naphthyl group is preferable.

The hetero atom which the cyclic hydrocarbon group for R_{y} may have is an atom other than carbon and hydrogen, and examples thereof include an oxygen atom, a nitrogen atom, a sulfur atom, and a halogen atom.

Examples of the cyclic hydrocarbon group which may have a hetero atom include a cyclic hydrocarbon group which may have —O—, —C(═O)—O—, —C(═O)—, —O—C(═O)—O—, —C(═O)—NH—, —NH—, —NH—C(=NH)—, (H may be substituted with a substituent such as an alkyl group, an acyl group or the like), —S—, —S(═O)₂—, or —S(═O)₂O—.

In particular, the cyclic hydrocarbon group containing a hetero atom is preferably a lactone-containing cyclic group, an —SO₂— containing cyclic group or a carbonate-containing cyclic group.

The term “lactone-containing cyclic group” refers to a cyclic group including a ring containing a —O—C(═O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

An “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

The term “carbonate-containing cyclic group” refers to a cyclic group including a ring containing a —O—C(═O)—O— structure (carbonate ring). The term “carbonate ring” refers to a single ring containing a —O—C(═O)—O— structure, and this ring is counted as the first ring. A carbonate-containing cyclic group in which the only ring structure is the carbonate ring is referred to as a monocyclic group, and groups containing other ring structures are described as polycyclic groups regardless of the structure of the other rings. The carbonate-containing cyclic group may be either a monocyclic group or a polycyclic group.

Divalent Hydrocarbon Group Represented by L Containing a Hetero Atom

The divalent linking group for L containing a hetero atom may be either an aliphatic hydrocarbon group or an aromatic hydrocarbon group.

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

Examples of the aliphatic hydrocarbon group include a linear or branched aliphatic hydrocarbon group, and an aliphatic hydrocarbon group containing a ring in the structure thereof can be given.

The linear or branched aliphatic hydrocarbon group may or may not have a substituent. Examples of the substituent are more specifically described below.

As examples of the hydrocarbon group containing a ring in the structure thereof, a cyclic aliphatic hydrocarbon group containing a hetero atom in the ring structure thereof and may have a substituent (a group in which two hydrogen atoms have been removed from an aliphatic hydrocarbon ring), a group in which the cyclic aliphatic hydrocarbon group is bonded to the terminal of the aforementioned chain-like aliphatic hydrocarbon group, and a group in which the cyclic aliphatic group is interposed within the aforementioned linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

Substituent for Divalent Linking Group Containing a Hetero Atom

A hydrogen atom of the divalent hydrocarbon group containing a hetero atom may be substituted with a substituent.

Examples of the substituent include a halogen atom such as a fluorine atom; a halogenated alkyl group (e.g., a group in which an alkyl group having 1 to 5 carbon atoms have part or all of the hydrogen atoms substituted with a fluorine atom, a chlorine atom, a bromine atom or an iodine atom), a hydroxy group, an alkoxy group such as a methoxy group (e.g., an alkoxy group having 1 to 6carbon atoms), a carboxy group, an alkoxycarbonyl group such as a methoxycarbonyl group (e.g., an alkoxycarbonyl group having 1 to 6 carbon atoms), an acyl group such as an acetyl group (e.g., an acyl group having 1 to 6 carbon atoms), a cyano group, an aryl group such as a phenyl group (e.g., an aryl group having 6 to 14 carbon atoms), an alkyl group such as a methyl group (e.g., an alkyl group having 1 to 20 carbon atoms, preferably an alkyl group having 1 to 10 carbon atoms, more preferably an alkyl group having 1 to 6 carbon atoms), an alkenyl group such as a vinyl group (e.g., an alkenyl group having 2 to 6 carbon atoms), a cycloalkyl group such as a cyclohexyl group (e.g., a cycloalkyl group having 3 to 12 carbon atoms), and a nitro group.

In the case where a hydrogen atom is present in the substituent, the hydrogen atom may be substituted with any of the above-mentioned substituents.

In general formula (2), n represents an integer of 0 to 20, preferably an integer of 0 to 10, and more preferably an integer of 0 to 5.

In the present invention, in the component (B), the anion represented by general formula (2) is more preferably an anion represented by general formula (2-1) or (2-2) shown below.

[Chemical Formula 8.]

R_{z}—OC(═O)—CF₂—SO₃⁻ (2-1)

In the formula, R_{z} represents a lactone-containing cyclic group.

[Chemical Formula 9.]

R_{w}—C(═O)O-L-(CX₂)ₙ—CF₂—SO₃⁻ (2-2)

In the formula, R_{w} represents a polycycloalkyl group; L represents a single bond or a divalent hydrocarbon group containing a hetero atom, provided that a hydrogen atom of the divalent hydrocarbon group containing a hetero atom may be substituted with a substituent; each X independently represents H or F; and n represents an integer of 0 to 10.

The anion represented by general formula (2-2) is most preferably an anion represented by general formula (2-2-1) or (2-2-2) shown below.

[Chemical Formula 10.]

R_{w}—C(═O)O—CH₂—CF₂—SO₃⁻

[Chemical Formula 11.]

R_{w}—C(═O)O—(CF₂)ₙ—CHF—CF₂—SO₃⁻

In general formulae (2-2), (2-2-1) and (2-2-2), the polycycloalkyl group for R_{w} refers to a group in which one hydrogen atom has been removed from the aforementioned polycycloalkane. The polycycloalkane preferably has 7 to 12 carbon atoms, and specific examples thereof include adamantane, norbornane, isobornane, tricyclodecane and tetracyclododecane.

In general formulae (2-2), (2-2-1) and (2-2-2), the definitions of the symbols are the same as defined in the aforementioned general formula (2).

In the present invention, preferable examples of the component (B) include the anions of the following acid generators (A) to (D).

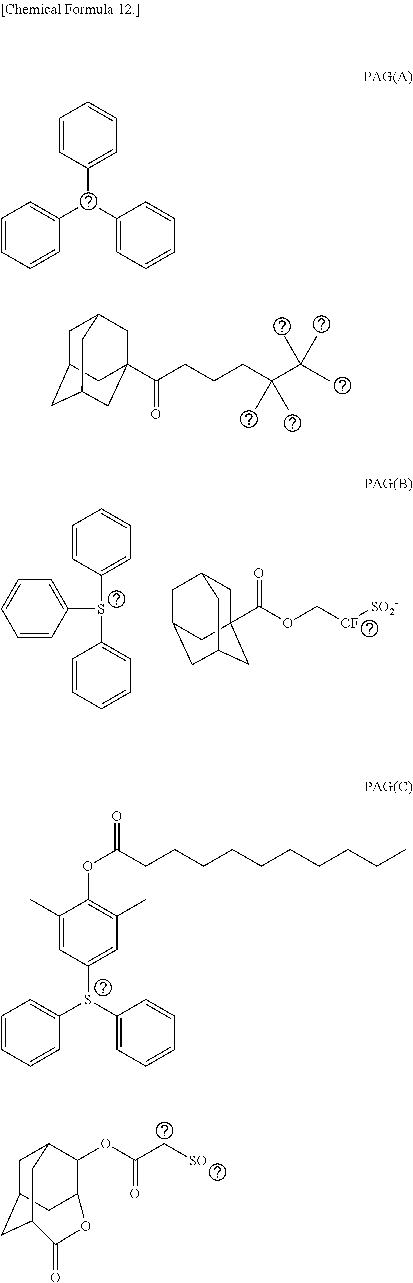

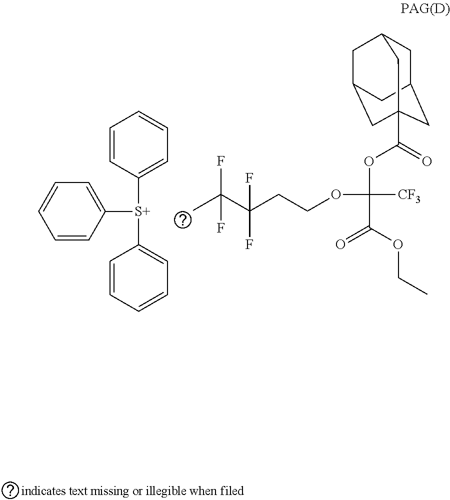 [SMILES: c1ccc([S+](c2ccccc2)c2ccccc2)cc1 ; CCOC(=O)C(OCCC(F)(F)C(C)(F)F)(OC(=O)C12CC3CC(CC(C3)C1)C2)C(F)(F)F]

{Cation Moiety}

The component (B) may contain an acid generator having a cation represented by (M^{m+})_{1/m}.

M^{m+} represents an organic cation having a valence of m. The organic cation for M^{m+} is not particularly limited, and examples thereof include cations represented by general formulae (ca-1) to (ca-4) shown below.

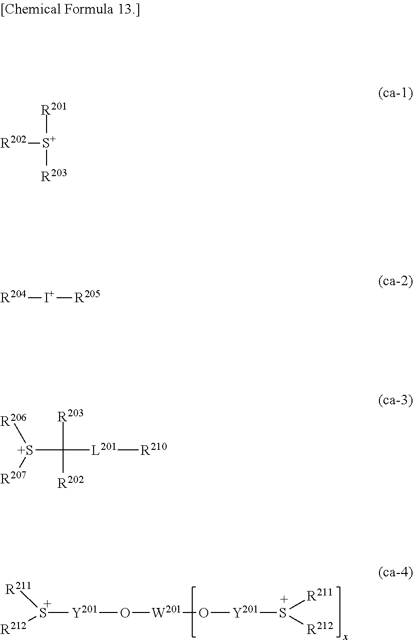

In the formulae, R²⁰¹ to R²⁰⁷, R²¹¹ and R²¹² each independently represents an aryl group, an alkyl group or an alkenyl group, provided that two of R²⁰¹ to R²⁰³, R²⁰⁶ and R²⁰⁷, or R²¹¹ and R²¹² may be mutually bonded to form a ring with the sulfur atom; R²⁰⁸ and R²⁰⁹ each independently represents a hydrogen atom or an alkyl group of 1 to 5 carbon atoms; R²¹⁰ represents an aryl group which may have a substituent, an alkyl group which may have a substituent, an alkenyl group which may have a substituent, or an —SO₂— containing cyclic group which may have a substituent; L²⁰¹ represents —C(═O)— or —C(═O)—O—; Y²⁰¹ each independently represents an arylene group, an alkylene group or an alkenylene group; x represents 1 or 2; and W²⁰¹ represents a linking group having a valence of (x+1).

As the aryl group for R²⁰¹ to R²⁰⁷, R²¹¹ and R²¹², an unsubstituted aryl group of 6 to 20 carbon atoms can be mentioned, and a phenyl group or a naphthyl group is preferable.

The alkyl group for R²⁰¹ to R²⁰⁷, R²¹¹ and R²¹² is preferably a chain-like or cyclic alkyl group having 1 to 30 carbon atoms.

The alkenyl group for R²⁰¹ to R²⁰⁷, R²¹¹ and R²¹² preferably has 2 to 10 carbon atoms.

Specific examples of the substituent which R²⁰¹ to R²⁰⁷ and R²¹⁰ to R²¹² may have include an alkyl group, a halogen atom, a halogenated alkyl group, a carbonyl group, a cyano group, an amino group, an aryl group, and groups represented by formulae (ca-r-1) to (ca-r-7) shown below.

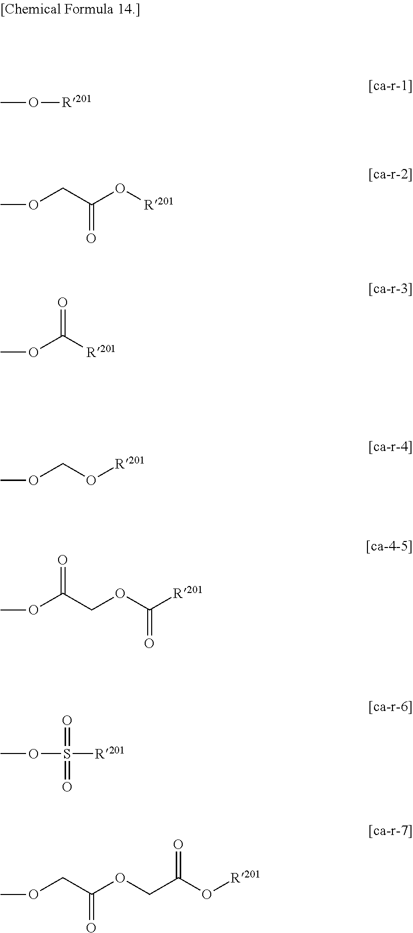

In the formulae, each R′²⁰¹ independently represents a hydrogen atom, a cyclic group which may have a substituent, a chain-like alkyl group which may have a substituent, or a chain-like alkenyl group which may have a substituent.

When R²⁰¹ to R²⁰³, R²⁰⁶, R²⁰⁷, R²¹¹ and R²¹² are mutually bonded to form a ring with the sulfur atom, these groups may be mutually bonded via a hetero atom such as a sulfur atom, an oxygen atom or a nitrogen atom, or a functional group such as a carbonyl group, —SO—, —SO₂—, —SO₃—, —COO—, —CONH— or —N(R_{N})— (wherein R_{N} represents an alkyl group of 1 to 5 carbon atoms). The ring containing the sulfur atom in the skeleton thereof is preferably a 3 to 10-membered ring, and most preferably a 5 to 7-membered ring. Specific examples of the ring formed include a thiophene ring, a thiazole ring, a benzothiophene ring, a thianthrene ring, a dibenzothiophene ring, a 9H-thioxanthene ring, a phenoxathiin ring, a tetrahydrothiophenium ring, and a tetrahydrothiopyranium ring.

R²⁰⁸ and R²⁰⁹ each independently represents a hydrogen atom or an alkyl group of 1 to 5 carbon atoms, preferably a hydrogen atom or an alkyl group of 1 to 3 carbon atoms, and when R²⁰⁸ and R²⁰⁹ each represents an alkyl group, R²⁰⁸ and R²⁰⁹ may be mutually bonded to form a ring.

R²¹⁰ represents an aryl group which may have a substituent, an alkyl group which may have a substituent, an alkenyl group which may have a substituent, or an —SO₂— containing cyclic group which may have a substituent.

Examples of the aryl group for R²¹⁰ include an unsubstituted aryl group of 6 to 20 carbon atoms, and a phenyl group or a naphthyl group is preferable.

As the alkyl group for R²¹⁰, a chain-like or cyclic alkyl group having 1 to 30 carbon atoms is preferable.

The alkenyl group for R²¹⁰ preferably has 2 to 10 carbon atoms.

As the —SO₂— containing cyclic group for R²¹⁰ which may have a substituent, an “—SO₂-containing polycyclic group” is preferable.

Each Y²⁰¹ independently represents an arylene group, an alkylene group or an alkenylene group.

Examples of the arylene group for Y²⁰¹ include a group in which one hydrogen atom has been removed from an aryl group.

Examples of the alkylene group and alkenylene group for Y²⁰¹ include groups in which one hydrogen atom has been removed from a chain-like alkyl group or a chain-like alkenyl group.

In the formula (ca-4), x represents 1 or 2.

W²⁰¹ represents a linking group having a valence of (x+1), i.e., a divalent or trivalent linking group.

The divalent linking group for W²⁰¹ is preferably a divalent hydrocarbon group optionally having a substituent. The divalent linking group for W²⁰¹ may be linear, branched or cyclic, and cyclic is more preferable. Among these, an arylene group having two carbonyl groups, each bonded to the terminal thereof is preferable. Examples of the arylene group include a phenylene group and a naphthylene group, and a phenylene group is particularly desirable.

As the trivalent linking group for W²⁰¹, a group in which one hydrogen atom has been removed from the aforementioned divalent linking group for W²⁰¹ and a group in which the divalent linking group has been bonded to another divalent linking group can be mentioned. The trivalent linking group for W²⁰¹ is preferably a group in which 2 carbonyl groups are bonded to an arylene group.

Specific examples of preferable cations represented by formula (ca-1) include cations represented by formulae (ca-1-1) to (ca-1-63) shown below.

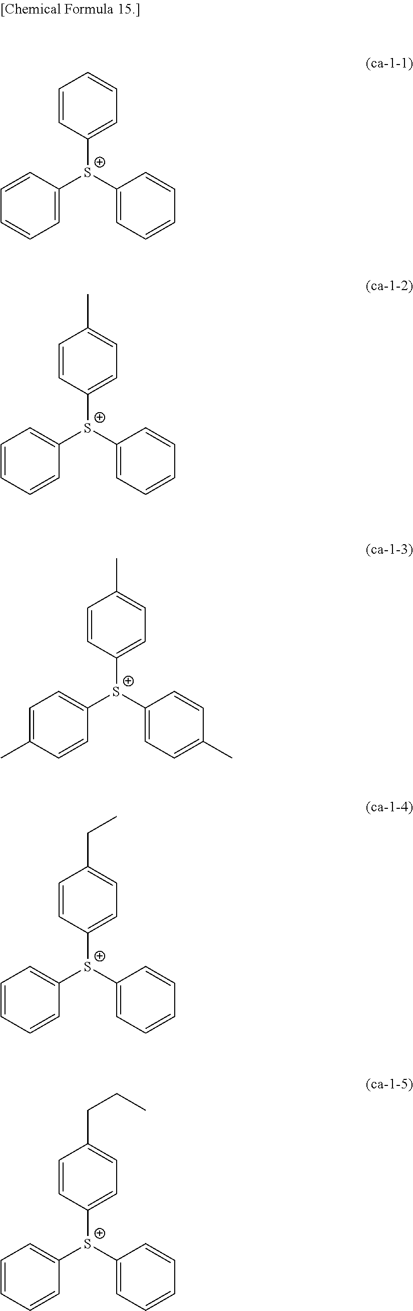

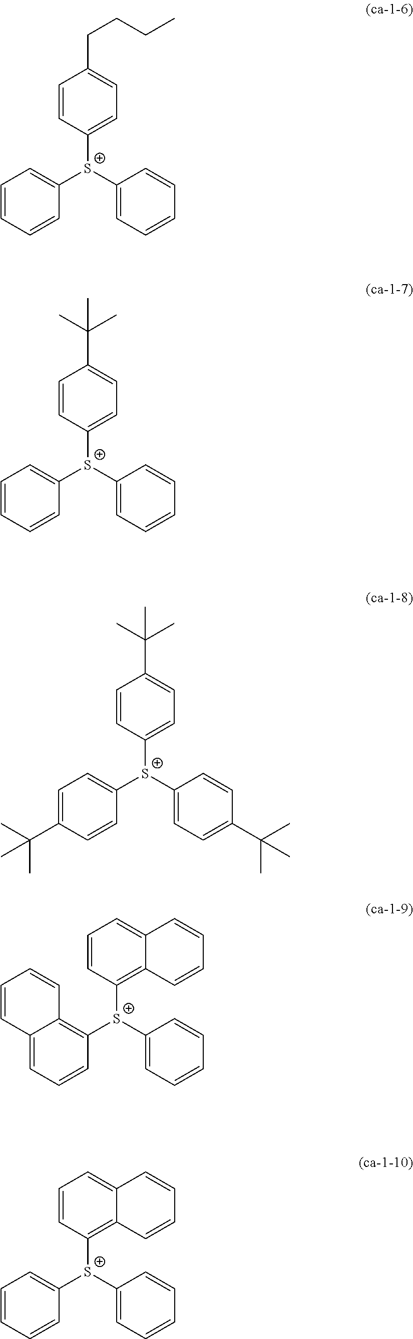

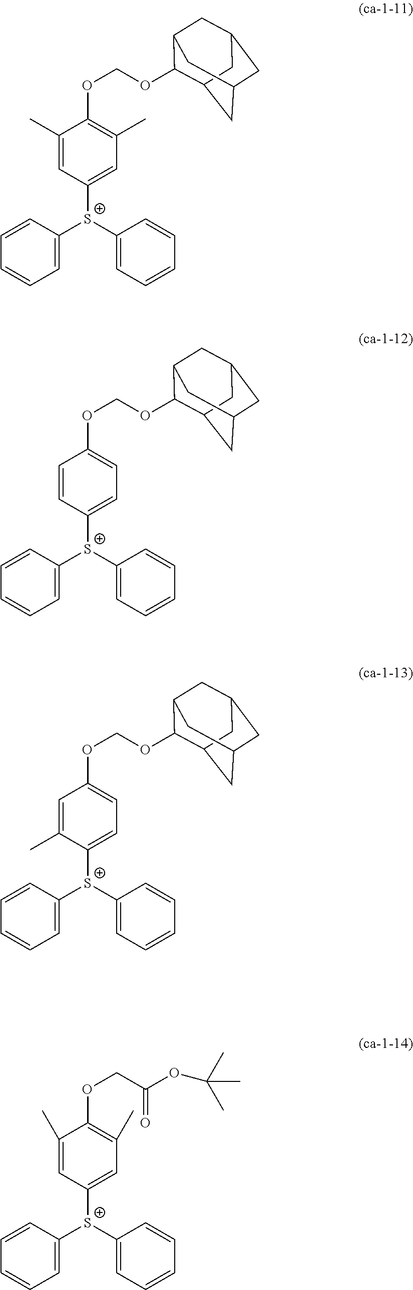

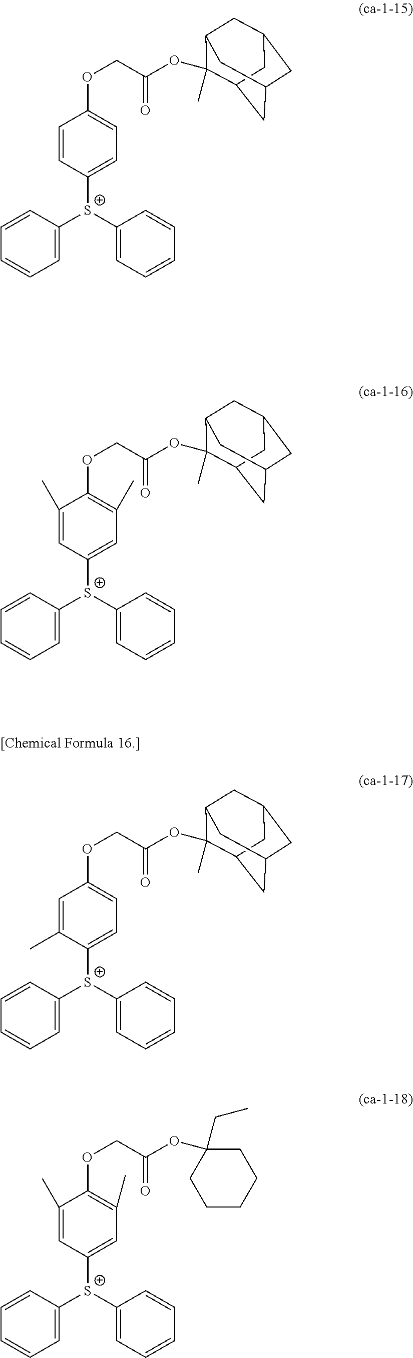

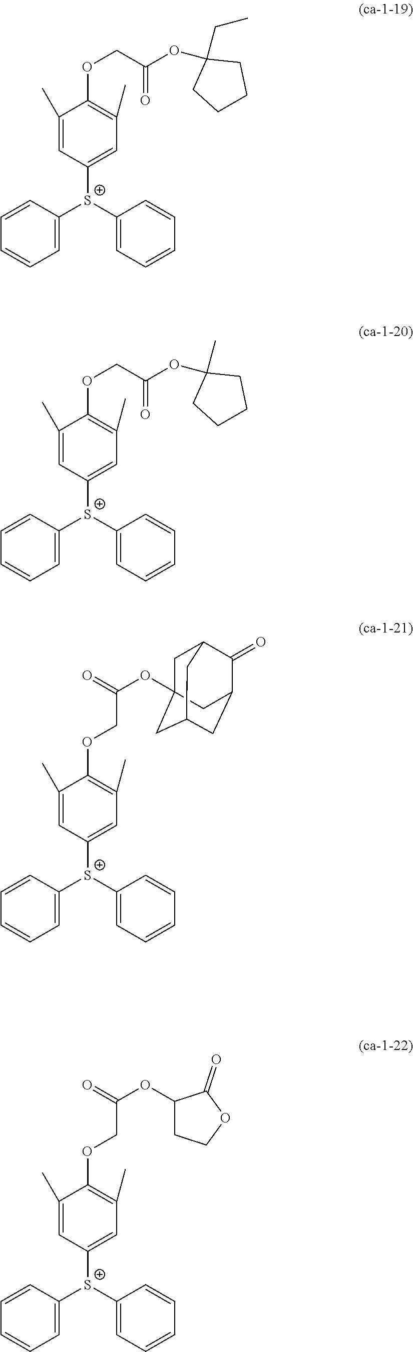

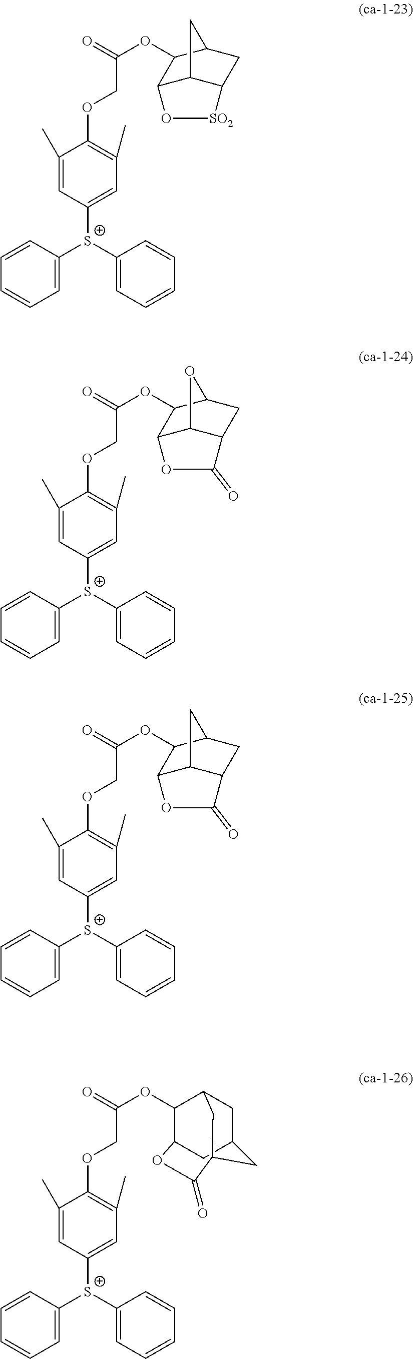

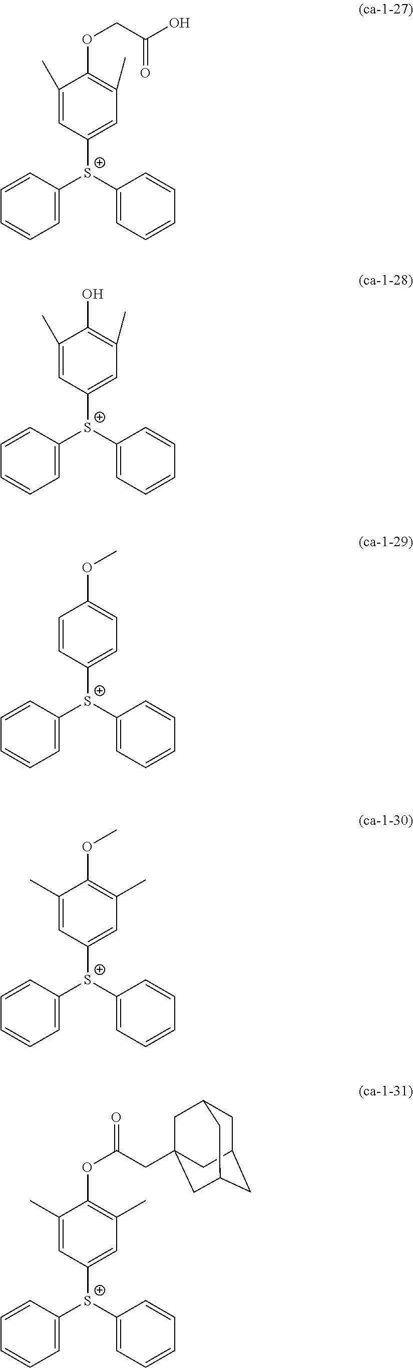

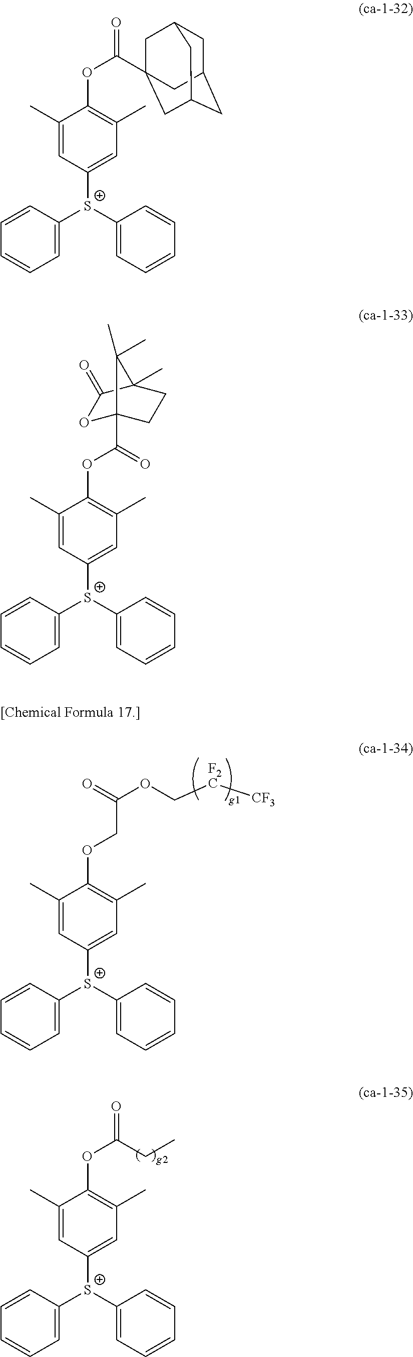

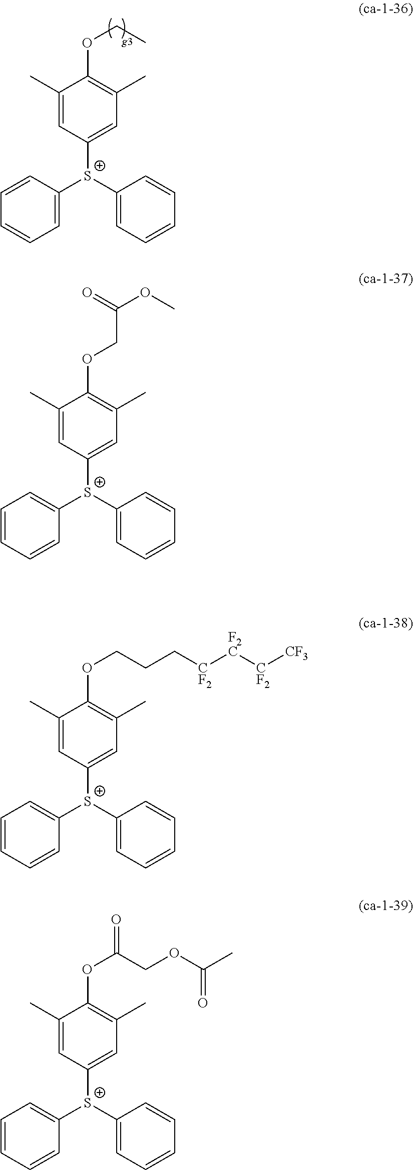

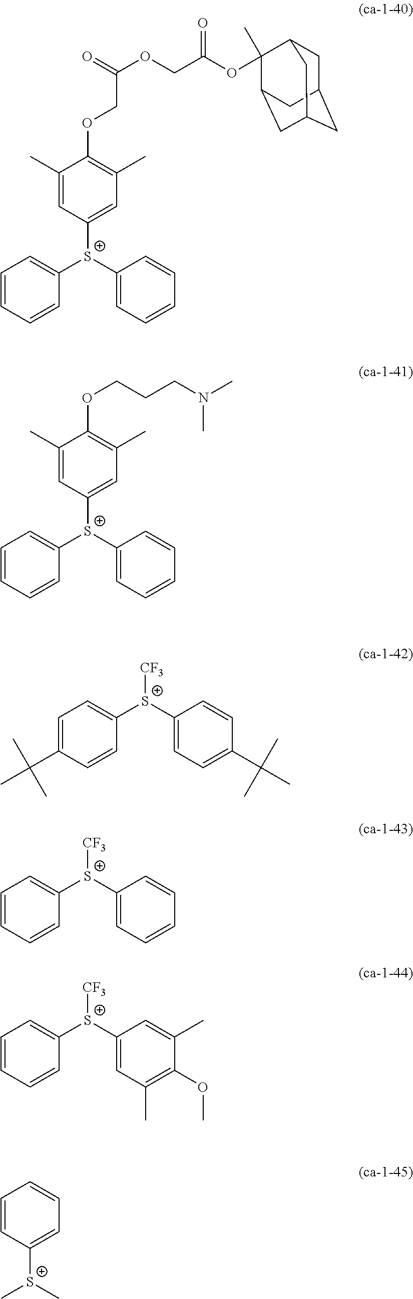

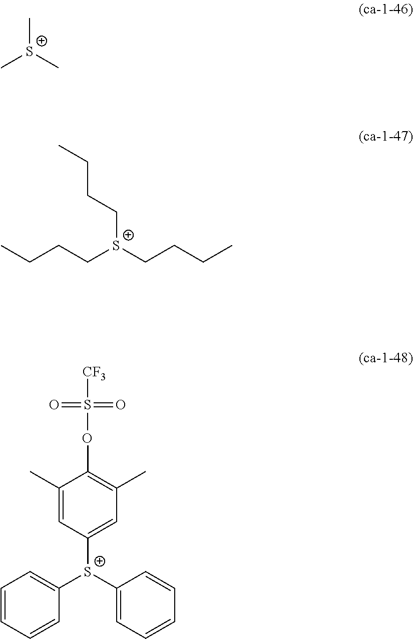

In the formulae, g1, g2 and g3 represent recurring numbers, wherein gl is an integer of 1 to 5, g2 is an integer of 0 to 20, and g3 is an integer of 0 to 20.

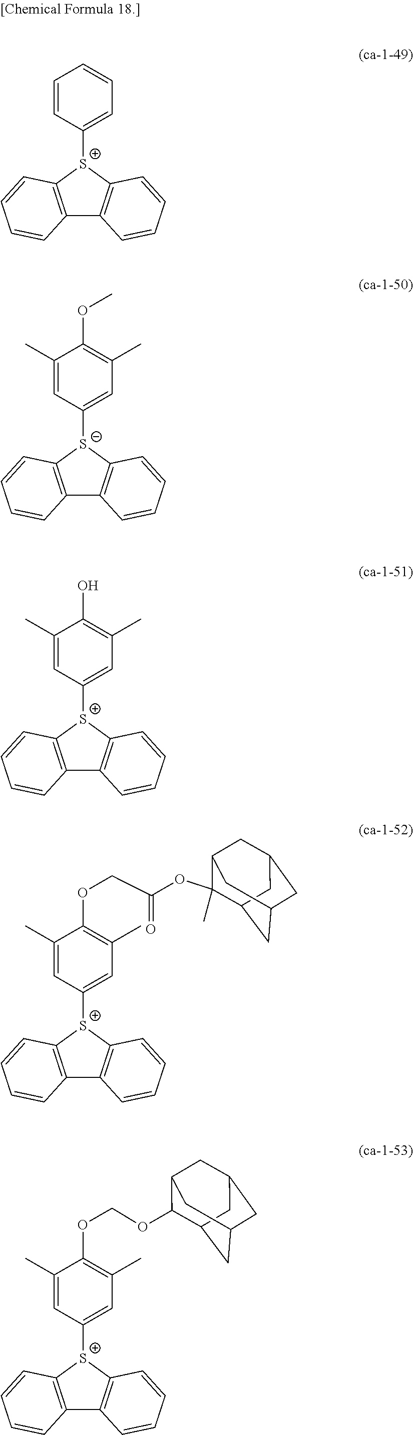

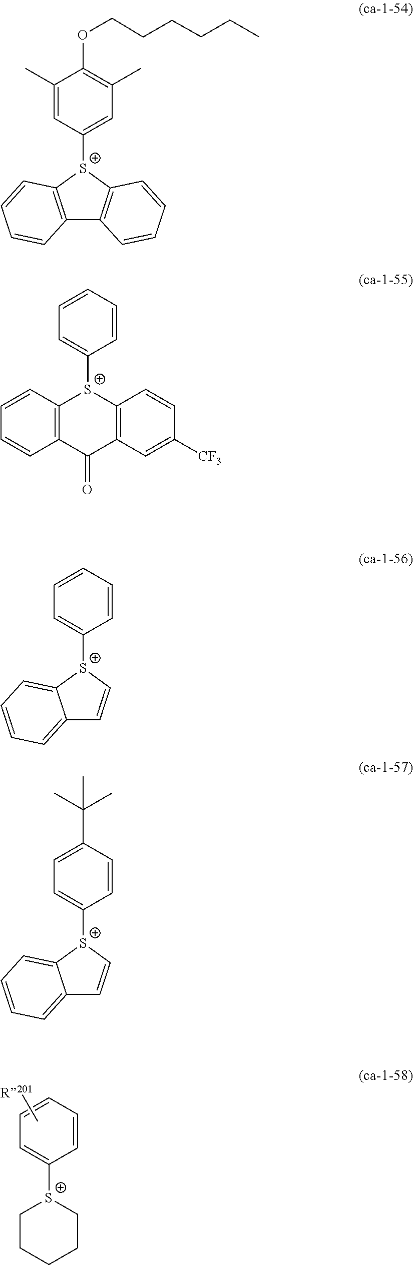

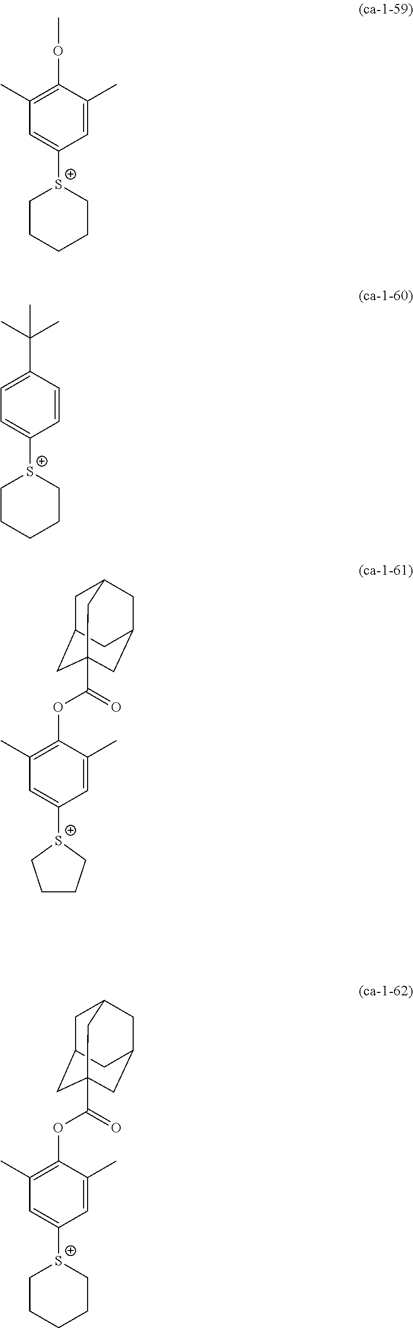

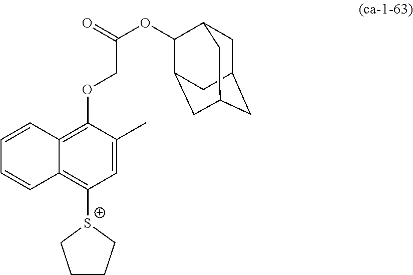

In the formulae, R″²⁰¹ represents a hydrogen atom or a substituent, and as the substituent, the same groups as those described above for substituting R²⁰¹ to R²⁰⁷ and R²¹⁰ to R²¹² can be mentioned.

As the acid-generator component (B), one kind of these acid generator components may be used alone, or two or more kinds of these acid generator components may be used in combination.

The amount of the component(B) relative to 100 parts by weight of the component (A) is preferably 0.5 to 60 parts by weight, more preferably 1 to 50 parts by weight, and still more preferably 1 to 40 parts by weight.

When the amount of the component (B) is within the above-mentioned range, formation of a resist pattern can be satisfactorily performed. Further, by virtue of the above-mentioned range, when each of the components are dissolved in an organic solvent, a homogeneous solution may be more reliably obtained and the storage stability of the resist composition becomes satisfactory.

<Other Components>

The resist composition of the present invention may contain, in addition to the aforementioned components (A) and (B), any other components other than the components (A) and (B). Examples of the other components include the component (D), the component (E), the component (F) and the component (S) described below.

[Component (D): Acid Diffusion Control Agent]

The resist composition of the present embodiment may include, in addition to the components (A) and (B), an acid diffusion control agent (hereafter, sometimes referred to as “component (D)”).

The component (D) functions as an acid diffusion control agent, i.e., a quencher which traps the acid generated from the component (B) and the like upon exposure.

In the present invention, the component (D) may be a photodecomposable base (D1) (hereafter, referred to as “component (D1)”) which is decomposed upon exposure and then loses the ability of controlling of acid diffusion, or a nitrogen-containing organic compound (D2) (hereafter, referred to as “component (D2)”) which does not fall under the definition of component (D1).

Component (D1)

When a resist pattern is formed using a resist composition containing the component (D1), the contrast between exposed portions and unexposed portions is improved.

The component (D1) is not particularly limited, as long as it is decomposed upon exposure and then loses the ability of controlling of acid diffusion. As the component (D1), at least one compound selected from the group consisting of a compound represented by general formula (d1-1) shown below (hereafter, referred to as “component (d1-1)”), a compound represented by general formula (d1-2) shown below (hereafter, referred to as “component (d1-2)”) and a compound represented by general formula (d1-3) shown below (hereafter, referred to as “component (d1-3)”) is preferably used.

At exposed portions, the components (d1-1) to (d1-3) are decomposed and then lose the ability of controlling of acid diffusion (i.e., basicity), and therefore the components (d1-1) to (d1-3) cannot function as a quencher, whereas at unexposed portions, the components (d1-1) to (d1-3) functions as a quencher.

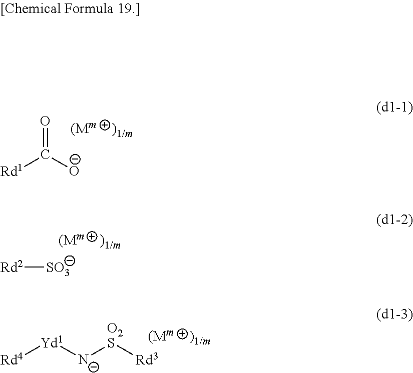

In the formulae, Rd¹ to Rd⁴ [symbol] represent a cyclic group which may have a substituent, a chain-like alkyl group which may have a substituent or a chain-like alkenyl group which may have a substituent, provided that, the carbon atom adjacent to the sulfur atom within the Rd² in the formula (d1-2) has no fluorine atom bonded thereto; Yd¹ represents a single bond or a divalent linking group; and each M^{m+} independently represents an organic cation having a valence of m.

{Component (d1-1)}

Anion Moiety

In formula (d1-1), Rd¹ represents a cyclic group which may have a substituent, a chain-like alkyl group which may have a substituent or a chain-like alkenyl group which may have a substituent, and is the same groups as those defined above for R¹⁰¹.

Among these, as the group for Rd¹, an aromatic hydrocarbon group which may have a substituent, an aliphatic cyclic group which may have a substituent and a chain-like alkyl group which may have a substituent are preferable. Examples of the substituent for these groups include a hydroxy group, an oxo group, an alkyl group, an aryl group, a fluorine atom, a fluorinated alkyl group, a lactone-containing cyclic group represented by any one of the aforementioned formulae (a2-r-1) to (a2-r-7), an ether bond, an ester bond, and a combination thereof. In the case where an ether bond or an ester bond is included as the substituent, the substituent may be bonded via an alkylene group, and a linking group represented by any one of formulae (y-a1-1) to (y-a1-5) shown below is preferable.

The aromatic hydrocarbon group is preferably an aryl group such as a phenyl group or a naphthyl group.

Examples of the aliphatic cyclic group include groups in which one or more hydrogen atoms have been removed from a polycycloalkane such as adamantane, norbornane, isobornane, tricyclodecane or tetracyclododecane.

As the chain-like hydrocarbon group, a chain-like alkyl group is preferable. The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group.

In the case where the chain-like alkyl group is a fluorinated alkyl group having a fluorine atom or a fluorinated alkyl group, the fluorinated alkyl group preferably has 1 to 11 carbon atoms, more preferably 1 to 8 carbon atoms, and still more preferably 1 to 4 carbon atoms. The fluorinated alkyl group may contain an atom other than fluorine. Examples of the atom other than fluorine include an oxygen atom, a carbon atom, a hydrogen atom, a sulfur atom and a nitrogen atom.

As Rd¹, a fluorinated alkyl group in which part or all of the hydrogen atoms constituting a linear alkyl group have been substituted with fluorine atom(s) is preferable, and a fluorinated alkyl group in which all of the hydrogen atoms constituting a linear alkyl group have been substituted with fluorine atoms (i.e., a linear perfluoroalkyl group) is more preferable.

Specific examples of preferable anion moieties for the component (d1-1) are shown below.

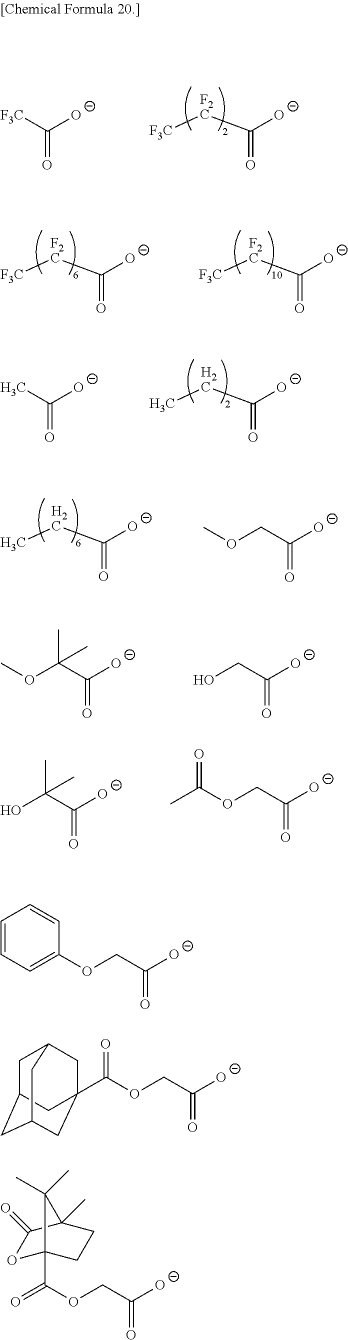

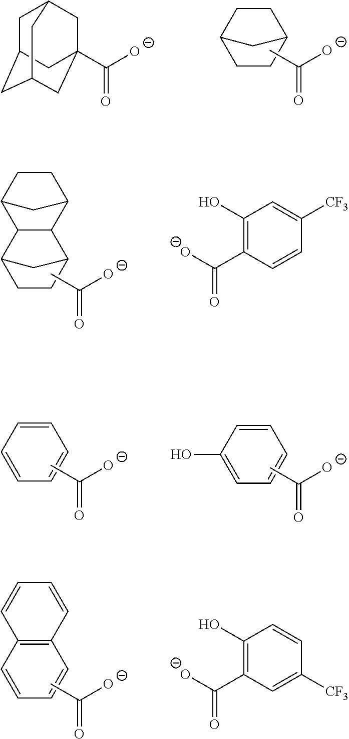

Cation Moiety

In formula (d1-1), M^{m+} represents an organic cation having a valence of m, and is the same as defined for the cation of the aforementioned component (B).

As the component (d1-1), one type of compound may be used, or two or more types of compounds may be used in combination.

{Component (d1-2)}

Anion Moiety

In formula (d1-2), Rd² represents a cyclic group which may have a substituent, a chain-like alkyl group which may have a substituent or a chain-like alkenyl group which may have a substituent, and is the same groups as those defined above for R¹⁰¹.

provided that, the carbon atom adjacent to the sulfur atom within Rd² group has no fluorine atom bonded thereto (i.e., the carbon atom adjacent to the sulfur atom within Rd² group does not substituted with a fluorine atom). As a result, the anion of the component (d1-2) becomes an appropriately weak acid anion, thereby improving the quenching ability of the component (D).

As Rd², an aliphatic cyclic group which may have a substituent is preferable, and a group in which one or more hydrogen atoms have been removed from adamantane, norbornane, isobornane, tricyclodecane, tetracyclododecane or camphor (which may have a substituent) is more preferable.

The hydrocarbon group for Rd² may have a substituent. As the substituent, the same groups as those described above for substituting the hydrocarbon group (e.g., aromatic hydrocarbon group, aliphatic hydrocarbon group) for Rd¹ in the formula (d1-1) can be mentioned.

Specific examples of preferable anion moieties for the component (d1-2) are shown below.

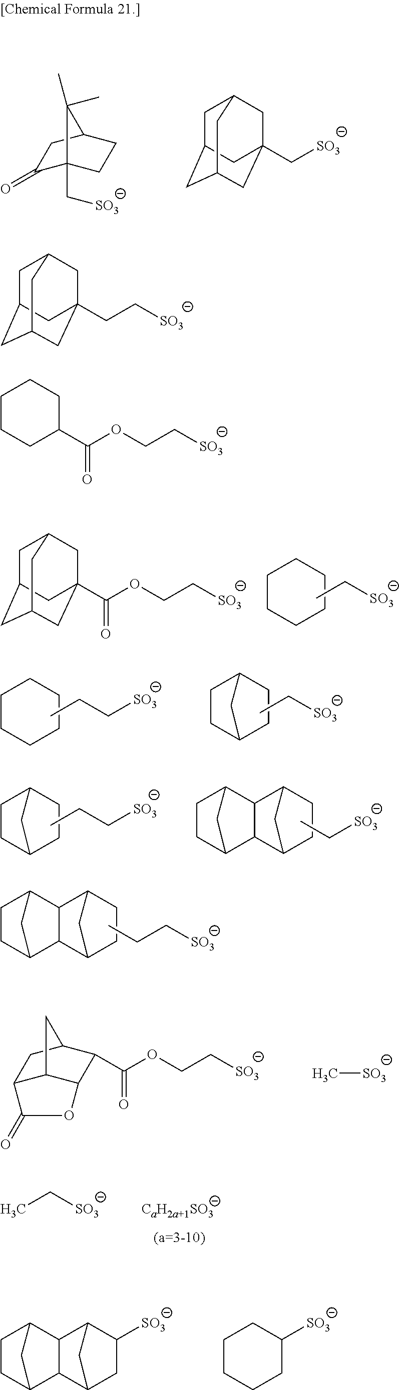

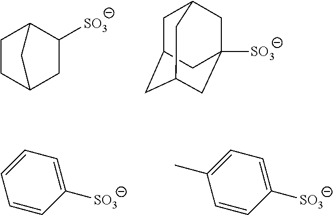

Cation Moiety

In formula (d1-2), M^{m+} is an organic cation having a valence of m, and is the same as defined for M^{m+} in the aforementioned formula (d1-1).

As the component (d1-2), one type of compound may be used, or two or more types of compounds may be used in combination.

{Component (d1-3)}

Anion Moiety

In formula (d1-3), Rd³ represents a cyclic group which may have a substituent, a chain-like alkyl group which may have a substituent or a chain-like alkenyl group which may have a substituent, and is the same groups as those defined above for R¹⁰¹, and a cyclic group containing a fluorine atom, a chain-like alkyl group or a chain-like alkenyl group is preferable. Among these, a fluorinated alkyl group is preferable, and more preferably the same fluorinated alkyl groups as those described above for Rd¹.

In formula (d1-3), Rd⁴ represents a cyclic group which may have a substituent, a chain-like alkyl group which may have a substituent or a chain-like alkenyl group which may have a substituent, and is the same groups as those defined above for R¹⁰¹.

Among these, an alkyl group which may have substituent, an alkoxy group which may have substituent, an alkenyl group which may have substituent or a cyclic group which may have substituent is preferable.

The alkyl group for Rd⁴ is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group. Part of the hydrogen atoms within the alkyl group for Rd⁴ may be substituted with a hydroxy group, a cyano group or the like.

The alkoxy group for Rd⁴ is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group and an ethoxy group are preferable.

As the alkenyl group for Rd⁴, the same groups as those described above for R¹⁰¹ may be mentioned, and a vinyl group, a propenyl group (an allyl group), a 1-methylpropenyl group and a 2-methylpropenyl group are preferable. These groups may have an alkyl group of 1 to 5 carbon atoms or a halogenated alkyl group of 1 to 5 carbon atoms as a substituent.

As the cyclic group for Rd⁴, the same groups as those described above for R¹⁰¹ may be mentioned. Among these, as the cyclic group, an alicyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. In the case where Rd⁴ is an alicyclic group, the resist composition may be satisfactorily dissolved in an organic solvent, and the lithography properties may be improved. Alternatively, in the case where Rd⁴ is an aromatic group, the resist composition exhibits excellent photoabsorption efficiency in lithography using EUV or the like as the exposure source, and the sensitivity and lithography properties may be improved.

In formula (d1-3), Yd¹ represents a single bond or a divalent linking group.

The divalent linking group for Yd¹ is not particularly limited, and examples thereof include a divalent hydrocarbon group (aliphatic hydrocarbon group, or aromatic hydrocarbon group) which may have a substituent and a divalent linking group containing a hetero atom. As such groups, the same divalent linking groups as those described above for Ya²¹ in the formula (a2-1) can be mentioned.

As Yd¹, a carbonyl group, an ester bond, an amide bond, an alkylene group or a combination of these is preferable. As the alkylene group, a linear or branched alkylene group is more preferable, and a methylene group or an ethylene group is still more preferable.

Specific examples of preferable anion moieties for the component (d1-3) are shown below.

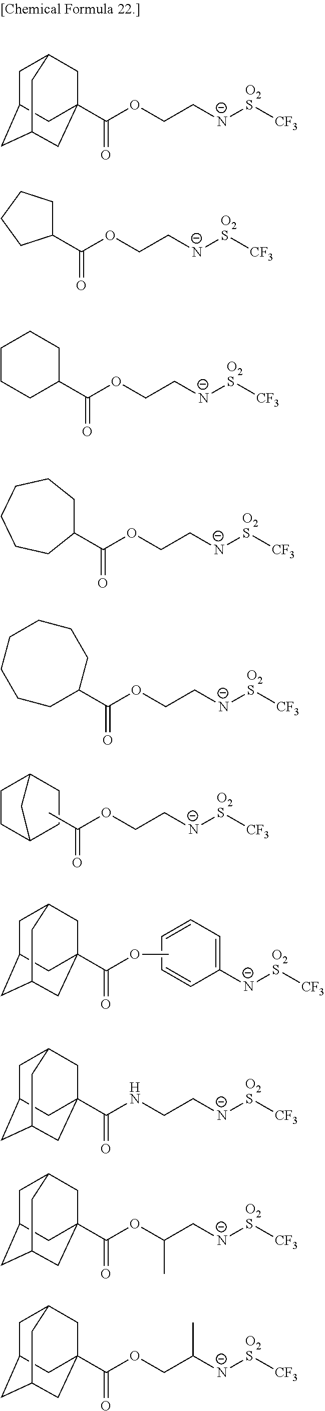

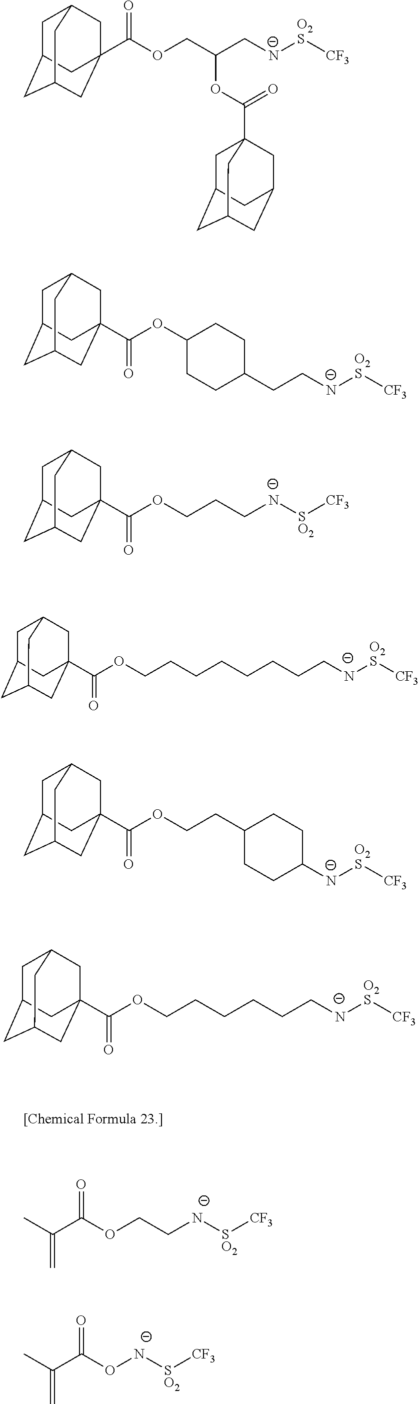

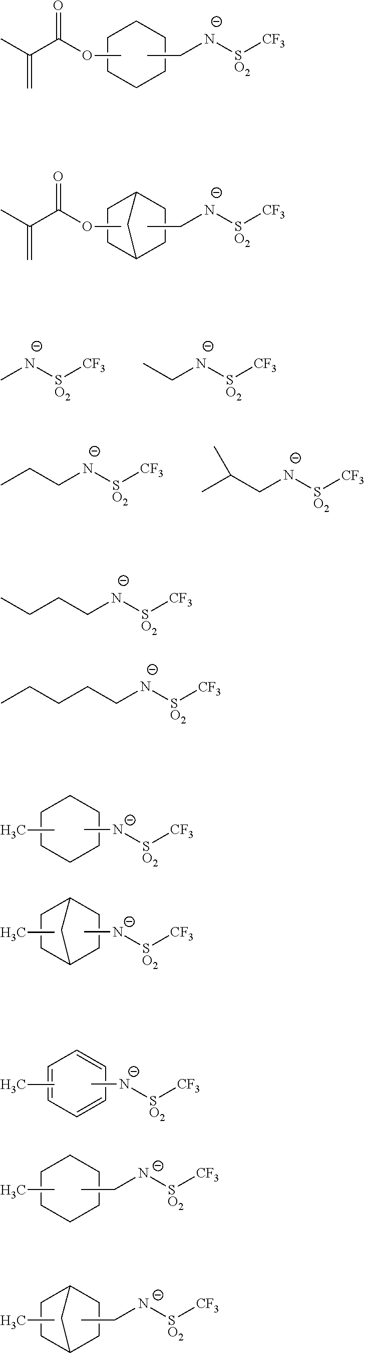

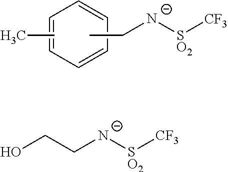

Cation Moiety

In formula (d1-3), M^{m+} is an organic cation having a valence of m, and is the same as defined for M^{m+} in the aforementioned formula (d1-1).

As the component (d1-3), one type of compound may be used, or two or more types of compounds may be used in combination.

As the component (D1), one type of the aforementioned components (d1-1) to (d1-3), or at least two types of the aforementioned components (d1-1) to (d1-3) can be used in combination.

The production methods of the components (d1-1) and (d1-2) are not particularly limited, and the components (d1-1) and (d1-2) can be produced by conventional methods.

The amount of the component (D1) relative to 100 parts by weight of the component (A) is preferably within a range from 0.5 to 15.0 parts by weight, more preferably from 0.5 to 10.0 parts by weight, and still more preferably from 1.0 to 8.0 parts by weight. When the amount of at least as large as the lower limit of the above-mentioned range, excellent lithography properties and excellent resist pattern shape can be obtained. On the other hand, when the amount of the component (D1) is no more than the upper limit of the above-mentioned range, sensitivity can be maintained at a satisfactory level, and through-put becomes excellent.

Component (D2)

The component (D) may contain a nitrogen-containing organic compound (D2) (hereafter, referred to as component (D2)) which does not fall under the definition of component (D1).

The component (D2) is not particularly limited, as long as it functions as an acid diffusion control agent, and does not fall under the definition of the component (D1). As the component (D2), any of the conventionally known compounds may be selected for use. Among these, an aliphatic amine is preferable, and a secondary aliphatic amine or tertiary aliphatic amine is more preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine Among these, trialkylamines of 5 to 10 carbon atoms are preferable, and tri-n-pentylamine and tri-n-octylamine are particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine)

Specific examples of the aliphatic monocyclic amine include piperidine, and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanolamine triacetate, and triethanolamine triacetate is preferable.

Further, as the component (D2), an aromatic amine may be used.

Examples of aromatic amines include aniline, pyridine, 4-dimethylaminopyridine, pyrrole, indole, pyrazole, imidazole and derivatives thereof, as well as diphenylamine, triphenylamine, tribenzylamine, 2,6-diisopropylaniline and N-tert-butoxycarbonylpyrrolidine.

As the component (D2), one kind of compound may be used alone, or two or more kinds of compounds may be used in combination.

The component (D2) is typically used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

As the component (D), one type of compound may be used, or two or more types of compounds may be used in combination.

When the resist composition of the present invention contains the component (D), the amount of the component (D) relative to 100 parts by weight of the component (A) is preferably within a range from 0.1 to 15 parts by weight, more preferably from 0.3 to 12 parts by weight, and still more preferably from 0.5 to 12 parts by weight. When the amount of the component (D) is at least as large as the lower limit of the above-mentioned range, various lithography properties (such as LWR) of the resist composition are improved. Further, a resist pattern having an excellent shape can be obtained. On the other hand, when the amount of the component (D) is no more than the upper limit of the above-mentioned range, sensitivity can be maintained at a satisfactory level, and through-put becomes excellent.

In the present embodiment, the component (D) preferably includes a compound (D0) represented by general formula (d0) shown below. The compound (D0) preferably includes a compound (D11) shown below. In the case where the acid diffusion control agent (D) includes the compound (D0), the amount of the compound (D0) relative to 100 parts by weight of the component (A) is preferably 0.1 to 30 parts by weight, more preferably 0.3 to 20 parts by weight, and still more preferably 0.5 to 15 parts by weight. When the above-mentioned range is satisfied, the effects of the present invention are enhanced. In the component (D), the amount of the compound (D0) based on the total weight of the component (D) is preferably 25% by weight or more, more preferably 50% by weight or more, still more preferably 75% by weight or more, and may be even 100% by weight. When the amount is 25% by weight or more, the effects of the present invention are improved. In addition, it is presumed that the solubility in a solvent and sensitivity are also improved.

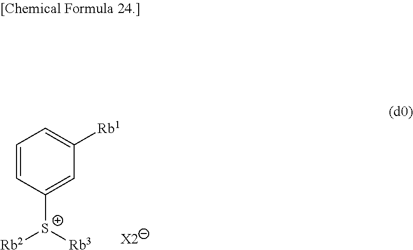

In formula (d0), Rb¹ represents an electron withdrawing group; Rb² and Rb³ each independently represents an aryl group which may have a substituent, an alkyl group which may have a substituent or an alkenyl group which may have a substituent, provided that Rb² and Rb³ may be mutually bonded to form a ring with the sulfur atom; and X2⁻ represents a monovalent counteranion capable of generating a weak acid.

In general formula (d0), X2⁻ represents a monovalent counteranion capable of generating a weak acid.

X2⁻ is not particularly limited as long as it is a monovalent counteranion capable of generating a weak acid, and examples thereof include a monovalent counteranion capable of generating an acid having an acid dissociation constant (pKa) of more than 0, preferably 0.2 or more and an upper limit of about 10.

In the present invention, the anion for X1⁻ is the same as defined for the anion moiety within the aforementioned formulae (d1-1) to (d1-3).

[Component (F): Fluorine Additive]

In the present embodiment, the resist composition may further include a fluorine additive (hereafter, referred to as “component (F)”) for imparting water repellency to the resist film.

As the component (F), for example, a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be used. Specific examples of the component (F) include polymers having a structural unit (f1) represented by general formula (f1-1) shown below. However, polymeric compounds which fall under the definition of the aforementioned component (A1) are excluded.

As the polymer having a structural unit (f1), a polymer (homopolymer) consisting of a structural unit (f1); a copolymer of a structural unit (f1) and a structural unit represented by general formula (m-1) shown below; and a copolymer of a structural unit (f1), a structural unit derived from acrylic acid or methacrylic acid, and a structural unit represented by general formula (m-1) shown below.

As the structural unit represented by general formula (m-1), a structural unit derived from 1-ethyl-1cyclooctyl (meth)acrylate or a structural unit derived from 1-methyl-1-adamantyl (meth)acrylate is preferable.

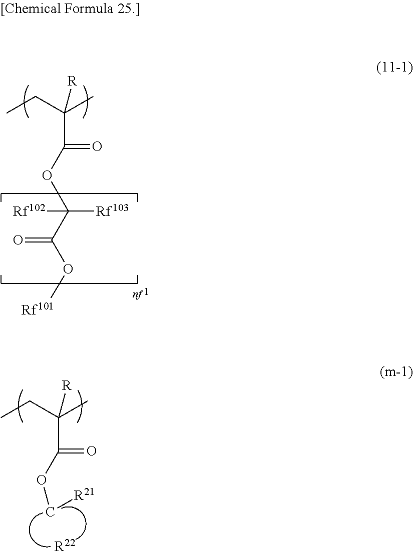

In the formulae, each R independently represents a hydrogen atom, an alkyl group of 1 to 5 carbon atoms or a halogenated alkyl group of 1 to 5 carbon atoms; in formula (f1-1), Rf¹⁰² and Rf¹⁰³ each independently represents a hydrogen atom, a halogen atom, an alkyl group of 1 to 5 carbon atoms or a halogenated alkyl group of 1 to 5 carbon atoms, provided that Rf¹⁰² and Rf¹⁰³ may be the same or different; nf¹ represents an integer of 0 to 5; and Rf¹⁰¹ represents an organic group containing a fluorine atom. In formula (m-1), R²¹ represents an alkyl group; R²² is a group which forms an aliphatic cyclic group together with a carbon atom having R²² bonded thereto.

In formula (f1-1), R represents a hydrogen atom, an alkyl group of 1 to 5 carbon atoms or a halogenated alkyl group of 1 to 5 carbon atoms. In formula (f1-1), R is the same as defined for R in the aforementioned formula (1).

As R, a hydrogen atom, an alkyl group of 1 to 5 carbon atoms or a fluorinated alkyl group of 1 to 5 carbon atoms is preferable, and in terms of industrial availability, a hydrogen atom or an alkyl group of 1 to 5 carbon atoms is more preferable, an alkyl group of 1 to 5 carbon atoms is still more preferable, and a methyl group is still most preferable.

In formula (f1-1), examples of the halogen atom for Rf¹⁰² and Rf¹⁰³ include a fluorine atom, a chlorine atom, a bromine atom and an iodine atom, and a fluorine atom is particularly desirable. Examples of the alkyl group of 1 to 5 carbon atoms for Rf¹⁰² and Rf¹⁰³ include the same alkyl group of 1 to 5 carbon atoms as those described above for R, and a methyl group or an ethyl group is preferable. Specific examples of the halogenated alkyl group of 1 to 5 carbon atoms represented by Rf¹⁰² or Rf¹⁰³ include groups in which part or all of the hydrogen atoms of the aforementioned alkyl groups of 1 to 5 carbon atoms have been substituted with halogen atoms.

Examples of the halogen atom include a fluorine atom, a chlorine atom, a bromine atom and an iodine atom, and a fluorine atom is particularly desirable. Among these examples, as Rf¹⁰² and Rf¹⁰³, a hydrogen atom, a fluorine atom or an alkyl group of 1 to 5 carbon atoms is preferable, and a hydrogen atom, a fluorine atom, a methyl group or an ethyl group is more preferable.

In formula (f1-1), nf¹ represents an integer of 0 to 5, preferably an integer of 0 to 3, and more preferably 0 or 1.

In formula (f1-1), Rf¹⁰¹ represents an organic group containing a fluorine atom, and is preferably a hydrocarbon group containing a fluorine atom.

The hydrocarbon group containing a fluorine atom may be linear, branched or cyclic, and preferably has 1 to 20 carbon atoms, more preferably 1 to 15 carbon atoms, and most preferably 1 to 10 carbon atoms.

It is preferable that the hydrocarbon group having a fluorine atom has 25% or more of the hydrogen atoms within the hydrocarbon group fluorinated, more preferably 50% or more, and most preferably 60% or more, as the hydrophobicity of the resist film during immersion exposure is enhanced.

Among these, as Rf¹⁰¹, a fluorinated hydrocarbon group of 1 to 5 carbon atoms is preferable, and a trifluoromethyl group, —CH₂—CF₃, —CH₂—CF₂—CF₃, —CH(CF₃)₂, —CH₂—CH₂—CF₃, and —CH₂—CH₂—CF₂—CF₂—CF₂—CF₃ are most preferable.

In formula (m-1), the alkyl group for R²¹ may be linear, branched or cyclic, and is preferably linear or branched. The linear alkyl group preferably has 1 to 5 carbon atoms, more preferably 1 to 4, and still more preferably 1 or 2. Specific examples include a methyl group, an ethyl group, an n-propyl group, an n-butyl group, and an n-pentyl group. Among these examples, a methyl group, an ethyl group or an n-butyl group is preferable, and a methyl group or an ethyl group is more preferable. The branched alkyl group preferably has 3 to 10 carbon atoms, and more preferably 3 to 5. Specific examples of such branched alkyl groups include an isopropyl group, an isobutyl group, a tert-butyl group, an isopentyl group and a neopentyl group, and an isopropyl group is particularly desirable.

In formula (m-1), R²² is a group which forms an aliphatic cyclic group together with a carbon atom having R²² bonded thereto. The aliphatic cyclic group formed by R²² may be polycyclic or monocyclic. As the monocyclic aliphatic hydrocarbon group, a group in which one or more hydrogen atoms have been removed from a monocycloalkane is preferable. The monocycloalkane preferably has 3 to 10 carbon atoms, and examples thereof include cyclopentane, cyclohexane and cyclooctane. As the polycyclic aliphatic hydrocarbon group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The weight average molecular weight (Mw) (the polystyrene equivalent value determined by gel permeation chromatography) of the component (F) is preferably 1,000 to 50,000, more preferably 5,000 to 40,000, and most preferably 10,000 to 30,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (F) is preferably 1.0 to 5.0, more preferably 1.0 to 3.0, and most preferably 1.2 to 2.5.

As the component (F), one type may be used alone, or two or more types may be used in combination.

When the resist composition contains the component (F), the component (F) is used in an amount within a range from 0.5 to 10 parts by weight, relative to 100 parts by weight of the component (A).

If desired, other miscible additives can also be added to the resist composition of the present invention. Examples of such miscible additives include additive resins for improving the performance of the resist film, dissolution inhibitors, plasticizers, stabilizers, colorants, halation prevention agents, and dyes.

[Component (S): Organic Solvent]

The resist composition of the present embodiment may be prepared by dissolving the resist materials for the resist composition in an organic solvent (hereafter, referred to as “component (S)”).

The component (S) may be any organic solvent which can dissolve the respective components to give a homogeneous solution, and any organic solvent can be appropriately selected from those which have been conventionally known as solvents for a chemically amplified resist composition.

Examples thereof include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and dimethylsulfoxide (DMSO).

The component (S) can be used individually, or in combination as a mixed solvent.

Among these, PGMEA, PGME, γ-butyrolactone, EL and cyclohexanone are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL or cyclohexanone is mixed as the polar solvent, the PGMEA:EL or cyclohexanone weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably 3:7 to 7:3. Furthermore, a mixed solvent of PGMEA, PGME and cyclohexanone is also preferable.

Further, as the component (S), a mixed solvent of at least one of PGMEA and EL with γ-butyrolactone is also preferable. The mixing ratio (former:latter) of such a mixed solvent is preferably from 70:30 to 95:5.

The amount of the component (S) is not particularly limited, and is appropriately adjusted to a concentration which enables coating of a coating solution to a substrate. In general, the component (S) is used in an amount such that the solid content of the resist composition becomes within the range from 1 to 20% by weight, and preferably from 2 to 15% by weight.

<<Method of Forming a Resist Pattern>>

The method of forming a resist pattern according to a second aspect of the present invention includes a step of forming a resist film on a substrate using a resist composition which generates acid upon exposure and exhibits changed solubility in a developing solution by the action of acid; a step of exposing the resist film; and a step of patterning the exposed resist film by development using a developing solution to form a resist pattern.

The method for forming a resist pattern may be performed, for example, as follows.

Firstly, a resist composition which generates acid upon exposure and exhibits changed solubility in a developing solution by the action of acid is applied to a substrate using a spinner or the like, and a bake treatment (post applied bake (PAB)) is conducted at a temperature of 80 to 150° C. for 40 to 120 seconds, preferably 60 to 90 seconds, to form a resist film.

As the resist composition, the aforementioned resist composition is used.

Following selective exposure of the thus formed resist film, either by exposure through a photomask having a predetermined pattern formed thereon (mask pattern) using an exposure apparatus such an ArF exposure apparatus, an electron beam lithography apparatus or an EUV exposure apparatus, or by patterning via direct irradiation with an electron beam without using a photomask.

Then, baking treatment (post exposure baking (PEB)) is conducted under temperature conditions of 80 to 150° C. for 40 to 120 seconds, and preferably 60 to 90 seconds.

Next, the resist film after the exposure and baking (PEB) is subjected to a developing treatment. The developing treatment is conducted using an alkali developing solution in the case of an alkali developing process, and a developing solution containing an organic solvent (organic developing solution) in the case of a solvent developing process.

After the developing treatment, it is preferable to conduct a rinse treatment. The rinse treatment is preferably conducted using pure water in the case of an alkali developing process, and a rinse solution containing an organic solvent in the case of a solvent developing process.

In the case of a solvent developing process, after the developing treatment or the rinsing, the developing solution or the rinse liquid remaining on the pattern can be removed by a treatment using a supercritical fluid.

After the developing treatment or the rinse treatment, drying is conducted. If desired, bake treatment (post bake) can be conducted following the developing. In this manner, a resist pattern can be obtained.

By conducting the above operations, a fine resist pattern can be formed.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be conducted using radiation such as ArF excimer laser, KrF excimer laser, F₂ excimer laser, extreme ultraviolet rays (EUV), vacuum ultraviolet rays (VUV), electron beam (EB), X-rays, and soft X-rays. The method of forming a resist pattern according to the present embodiment is effective to KrF excimer laser, ArF excimer laser, EB and EUV, and more effective to ArF excimer laser, EB and EUV.

The exposure of the resist film can be either a general exposure (dry exposure) conducted in air or an inert gas such as nitrogen, or immersion exposure (immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long as it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

In an alkali developing process, as the alkali developing solution used in the developing treatment, any conventional alkali developing may be appropriately selected which is capable of dissolving the aforementioned component (A) (component (A) prior to exposure). As an example of the alkali developing solution used in an alkali developing process, a 0.1 to 10% by weight aqueous solution of tetramethylammonium hydroxide (TMAH) may be given.

In a solvent developing process, as the organic solvent contained in the organic developing solution used in the developing treatment, any conventional organic solvent may be appropriately selected which is capable of dissolving the aforementioned component (A) (component (A) prior to exposure). Specific examples of the organic solvent include polar solvents such as ketone solvents, ester solvents, alcohol solvents, nitrile solvents, amide solvents and ether solvents, and hydrocarbon solvents. The developing solution may contain 80% by weight or more of an organic solvent.

A ketone solvent is an organic solvent containing C—C(═O)—C within the structure thereof. An ester solvent is an organic solvent containing C—C(═O)—O—C within the structure thereof. An alcohol solvent is an organic solvent containing an alcoholic hydroxy group in the structure thereof. An “alcoholic hydroxy group” refers to a hydroxy group bonded to a carbon atom of an aliphatic hydrocarbon group. A nitrile solvent is an organic solvent containing a nitrile group in the structure thereof. An amide solvent is an organic solvent containing an amide group within the structure thereof. An ether solvent is an organic solvent containing C—O—C within the structure thereof.

Some organic solvents have a plurality of the functional groups which characterizes the aforementioned solvents within the structure thereof. In such a case, the organic solvent can be classified as any type of the solvent having the characteristic functional group. For example, diethyleneglycol monomethylether can be classified as either an alcohol solvent or an ether solvent.

A hydrocarbon solvent consists of a hydrocarbon which may be halogenated, and does not have any substituent other than a halogen atom. Examples of the halogen atom include a fluorine atom, a chlorine atom, a bromine atom and an iodine atom, and a fluorine atom is preferable.

As the developing solution used in a solvent developing process, in terms of more reliably obtaining a resist pattern with high resolution, it is preferable to contain at least one member selected from the group consisting of an ester organic solvent and a ketone organic solvent, and it is more preferable to contain an ester organic solvent.

Examples of ester organic solvents include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate and propyl-3-methoxypropionate.

Among these examples, as an ester solvent, butyl acetate is preferable.

Examples of ketone organic solvents include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonylalcohol, acetylcarbinol, acetophenone, methyl naphthyl ketone, isophorone, propylenecarbonate, γ-butyrolactone and methyl amyl ketone (2-heptanone).

Among these examples, as a ketone organic solvent, methyl amyl ketone (2-heptanone) is preferable.

If desired, the organic developing solution may have a conventional additive blended. Examples of the additive include surfactants. The surfactant is not particularly limited, and for example, an ionic or non-ionic fluorine and/or silicon surfactant can be used.

As the surfactant, a non-ionic surfactant is preferable, and a fluorine surfactant or a silicon surfactant is more preferable.

When a surfactant is added to the organic developing solution, the amount thereof based on the total amount of the organic developing solution is generally 0.001 to 5% by weight, preferably 0.005 to 2% by weight, and more preferably 0.01 to 0.5% by weight.

The developing treatment can be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

As the organic solvent contained in the rinse liquid used in the rinse treatment after the developing in the case of a solvent developing process, any of the aforementioned organic solvents contained in the organic developing solution can be used which hardly dissolves the resist pattern. In general, at least one solvent selected from the group consisting of hydrocarbon organic solvents, ketone organic solvents, ester organic solvents, alcohol organic solvents, amide organic solvents and ether organic solvents is used. Among these, at least one solvent selected from the group consisting of hydrocarbon organic solvents, ketone organic solvents, ester organic solvents, alcohol organic solvents and amide organic solvents is preferable, more preferably at least one solvent selected from the group consisting of ester organic solvents and ketone organic solvents, and most preferably ester organic solvents.

These organic solvents can be used individually, or at least 2 solvents may be mixed together. Further, an organic solvent other than the aforementioned examples or water may be mixed together. However, in consideration of the development characteristics, the amount of water within the rinse liquid, based on the total amount of the rinse liquid is preferably 30% by weight or less, more preferably 10% by weight or less, still more preferably 5% by weight or less, and most preferably 3% by weight or less.

If desired, the rinse solution may have a conventional additive blended. Examples of the additive include surfactants. As the surfactant, the same surfactants as those described above can be mentioned, and a non-ionic surfactant is preferable, and a fluorine surfactant or a silicon surfactant is more preferable.

When a surfactant is added, the amount thereof based on the total amount of the rinse liquid is generally 0.001 to 5% by weight, preferably 0.005 to 2% by weight, and more preferably 0.01 to 0.5% by weight.

The rinse treatment using a rinse liquid (washing treatment) can be conducted by a conventional rinse method. Examples of the rinse method include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

### EXAMPLES

As follows is a description of examples of the present invention, although the scope of the present invention is by no way limited by these examples.

<Base Component of Resist Composition>

In the present examples, each of polymer-(1) to polymer-(3) and polymer-(5) to polymer (11) used as the base component was obtained by radical polymerization of monomers M-1 to M-9 which derive the structural units constituting each polymer at a predetermined molar ratio.

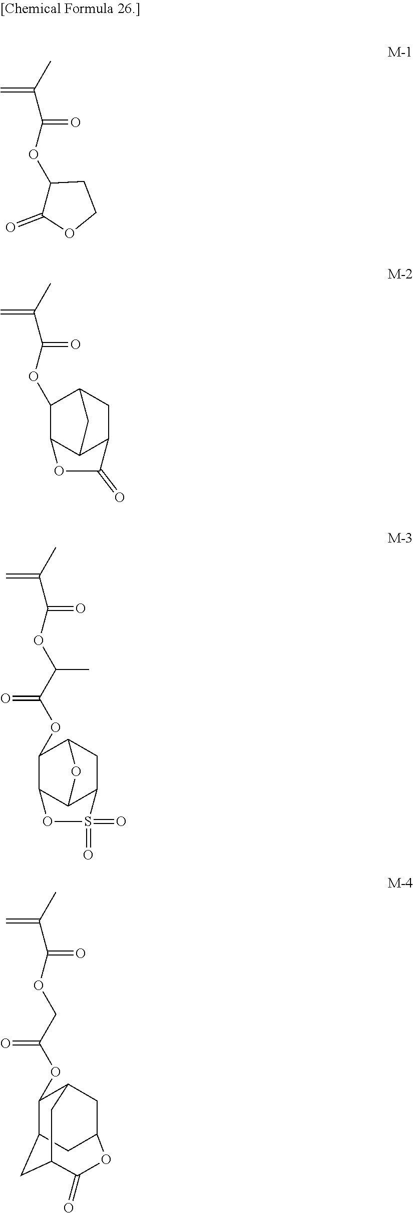

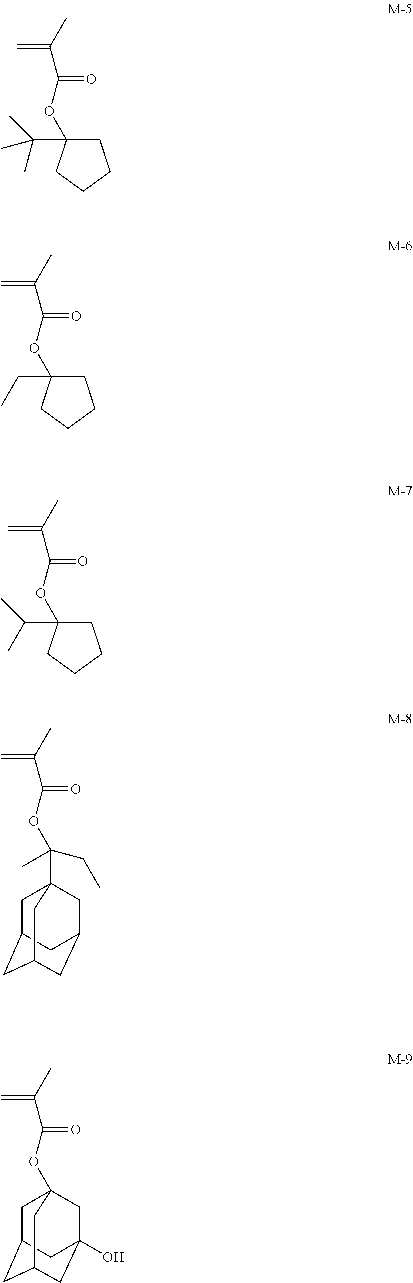

TABLE 1

| | Structural | Structural | Structural | Structural | Structural | | |
|---|---|---|---|---|---|---|---|
| | unit 1 | unit 2 | unit 3 | unit 4 | unit 5 | Molar ratio | Mw/PDI |
| Polymer-(1) | M-5 | M-1 | | | | 50/50 | 9100/1.63 |
| Polymer-(2) | M-5 | M-4 | M-8 | M-9 | | 20/40/30/10 | 8700/1.67 |
| Polymer-(3) | M-5 | M-3 | M-8 | M-9 | | 20/40/30/10 | 8800/1.65 |
| Polymer-(6) | M-5 | M-2 | | | | 50/50 | 8900/1.61 |
| Polymer-(7) | M-5 | M-2 | M-9 | | | 50/40/10 | 9200/1.65 |
| Polymer-(9) | M-5 | M-1 | M-2 | M-9 | | 50/20/20/10 | 8900/1.67 |
| Polymer-(10) | M-5 | M-1 | M-4 | M-9 | | 50/20/20/10 | 9300/1.68 |
| Polymer-(5) | | M-1 | M-7 | | | 50/50 | 8200/1.66 |
| Polymer-(8) | | M-2 | M-7 | | | 50/50 | 9300/1.66 |
| Polymer-(11) | | M-1 | M-4 | M-6 | M-9 | 20/20/50/10 | 9200/1.68 |

Regarding the molar ratio in the table, for example, the molar ratio of M-1:M-5 is indicated for polymer (1), and the same applies for polymer-(2), polymer-(3), and polymer-(5) to polymer (11).

<Production of Resist Composition: Examples 1 to 12, Comparative Examples 1 to 8>

The components shown in Tables 2 and 3 were mixed together and dissolved to obtain each resist composition.

TABLE 2

| | | | Acid diffusion | | |
|---|---|---|---|---|---|
| | Resin | PAG | control agent | Additive | |
| | (Component | (Component | (Component | (Component | Solvent |
| | (A)) | (B)) | (D)) | (F)) | (Component (S)) |
| Example 1 | Polymer-(1) | PAG-(A) | Quencher-(A) | Additive-(A) | PGMEA/PGME(2260/970) |
| | [100] | [8.1] | [5.0] | [2] | [3230] |
| Example 2 | Polymer-(1) | PAG-(B) | Quencher-(B) | Additive-(A) | PGMEA/PGME(2260/970) |
| | [100] | [6.5] | [3.2] | [2] | [3230] |
| Example 3 | Polymer-(1) | PAG-(C) | Quencher-(B) | Additive-(A) | PGMEA/PGME(2260/970) |
| | [100] | [6.54] | [3.2] | [2] | [3230] |
| Example 4 | Polymer-(1) | PAG-(D) | Quencher-(B) | Additive-(A) | PGMEA/PGME(2260/970) |
| | [100] | [9.5] | [3.2] | [2] | [3230] |
| Example 5 | Polymer-(2) | PAG-(C) | Quencher-(B) | Additive-(A) | PGMEA/PGME(2260/970) |
| | [100] | [6.54] | [3.2] | [2] | [3230] |
| Example 6 | Polymer-(3) | PAG-(A) | Quencher-(B) | Additive-(A) | PGMEA/PGME(2260/970) |
| | [100] | [8.1] | [3.2] | [2] | [3230] |
| Example 7 | Polymer-(1) | PAG-(B) | Quencher-(C) | Additive-(A) | PGMEA/PGME(2260/970) |
| | [100] | [6.5] | [4] | [2] | [3230] |
| Example 8 | Polymer-(6) | PAG-(B) | Quencher-(C) | Additive-(A) | PGMEA/PGME(2260/970) |
| | [100] | [6.5] | [4] | [2] | [3230] |
| Example 9 | Polymer-(7) | PAG-(B) | Quencher-(C) | Additive-(A) | PGMEA/PGME(2260/970) |
| | [100] | [6.5] | [4] | [2] | [3230] |
| Example | Polymer-(7) | PAG-(A) | Quencher-(C) | Additive-(A) | PGMEA/PGME(2260/970) |
| 10 | [100] | [6.2] | [4] | [2] | [3230] |
| Example | Polymer-(9) | PAG-(C) | Quencher-(B) | Additive-(A) | PGMEA/PGME(2260/970) |
| 11 | [100] | [6.54] | [3.25] | [2] | [3230] |
| Example | Polymer-(10) | PAG-(C) | Quencher-(B) | Additive-(A) | PGMEA/PGME(2260/970) |
| 12 | [100] | [6.54] | [3.25] | [2] | [3230] |
| Example | Polymer-(1) | PAG-(H) | Quencher-(B) | Additive-(A) | PGMEA/PGME(2260/970) |
| 13 | [100] | [9.0] | [3.5] | [1.5] | [3230] |

TABLE 3

| | | | Acid diffusion | | |
|---|---|---|---|---|---|
| | Resin | PAG | control agent | Additive | |
| | (Component | (Component | (Component | (Component | Solvent |
| | (A)) | (B)) | (D)) | (F)) | (Component (S)) |
| Comparative | Polymer-(1) | PAG-(E) | Quencher-(B) | Additive-(A) | PGMEA/PGME(2260/970) |
| Example 1 | [100] | [6.3] | [3.2] | [2] | [3230] |
| Comparative | Polymer-(1) | PAG-(F) | Quencher-(B) | Additive-(A) | PGMEA/PGME(2260/970) |
| Example 2 | [100] | [6.2] | [3.2] | [2] | [3230] |
| Comparative | Polymer-(1) | PAG-(G) | Quencher-(B) | Additive-(A) | PGMEA/PGME(2260/970) |
| Example 3 | [100] | [7.1] | [3.2] | [2] | [3230] |
| Comparative | Polymer-(5) | PAG-(B) | Quencher-(B) | Additive-(A) | PGMEA/PGME(2260/970) |
| Example 4 | [100] | [6.5] | [3.2] | [2] | [3230] |
| Comparative | Polymer-(8) | PAG-(B) | Quencher-(C) | Additive-(A) | PGMEA/PGME(2260/970) |
| Example 5 | [100] | [6.5] | [4] | [2] | [3230] |
| Comparative | Polymer-(1) | PAG-(E) | Quencher-(C) | Additive-(A) | PGMEA/PGME(2260/970) |
| Example 6 | [100] | [6.5] | [4] | [2] | [3230] |
| Comparative | Polymer-(9) | PAG-(E) | Quencher-(B) | Additive-(A) | PGMEA/PGME(2260/970) |
| Example 7 | [100] | [6.3] | [3.25] | [2] | [3230] |
| Comparative | Polymer-(11) | PAG-(C) | Quencher-(B) | Additive-(A) | PGMEA/PGME(2260/970) |
| Example 8 | [100] | [6.54] | [3.25] | [2] | [3230] |

In Tables 2 and 3, the reference characters indicate the following. The values in brackets [ ] indicate the amount (in terms of parts by weight) of the component added.

Polymer-(1) to polymer-(3) and polymer-(5) to polymer (11): the above polymer-(1) to polymer-(3) and polymer-(5) to polymer (11) in Table 1

PAG-(A) to PAG-(H): acid generators represented by the following chemical formulae

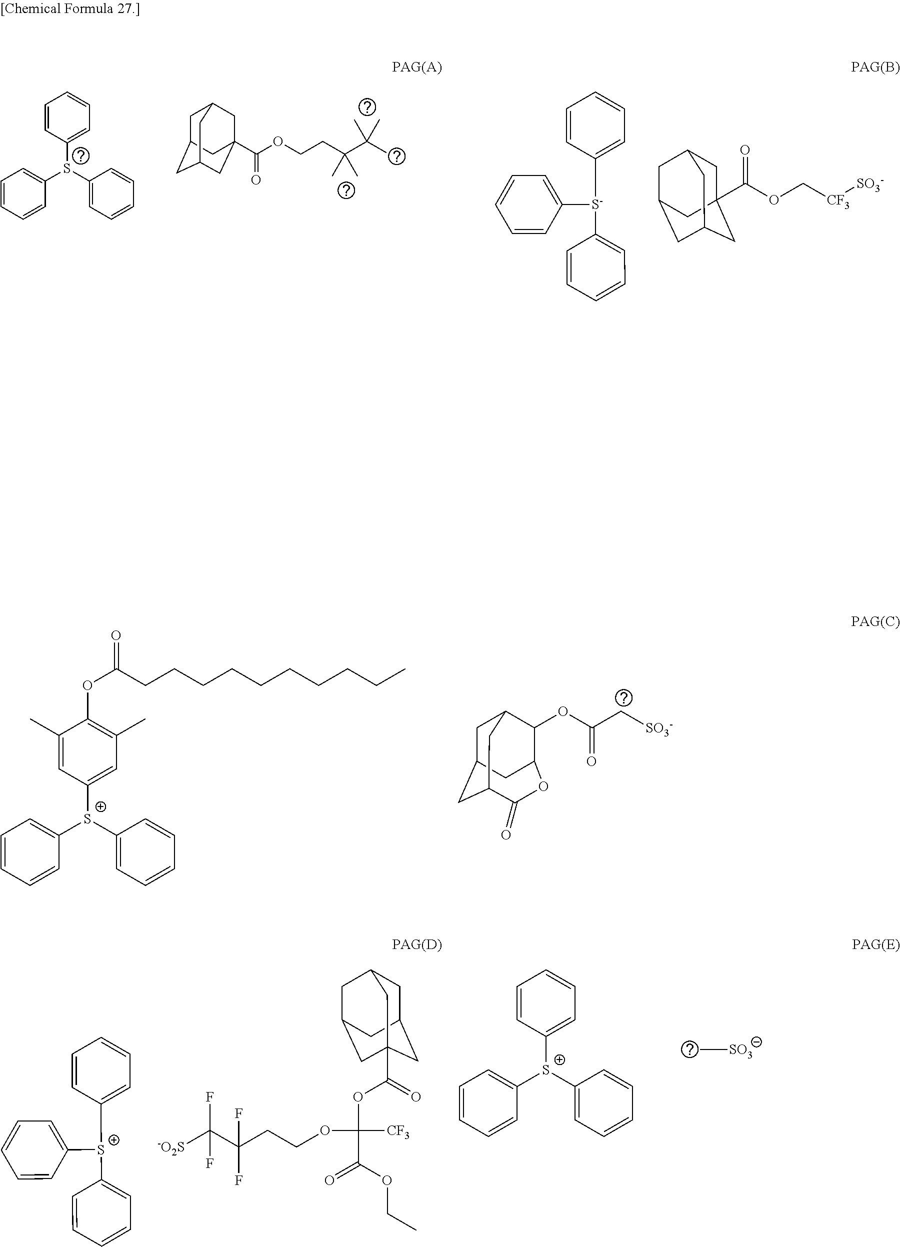

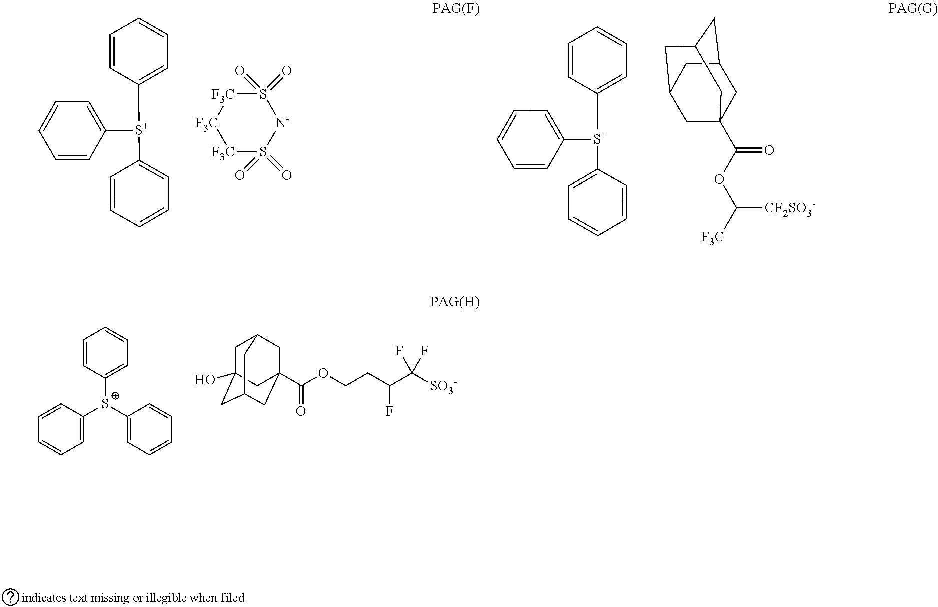

Quenchers (A) to (C): acid diffusion control agents represented by the following chemical formulae

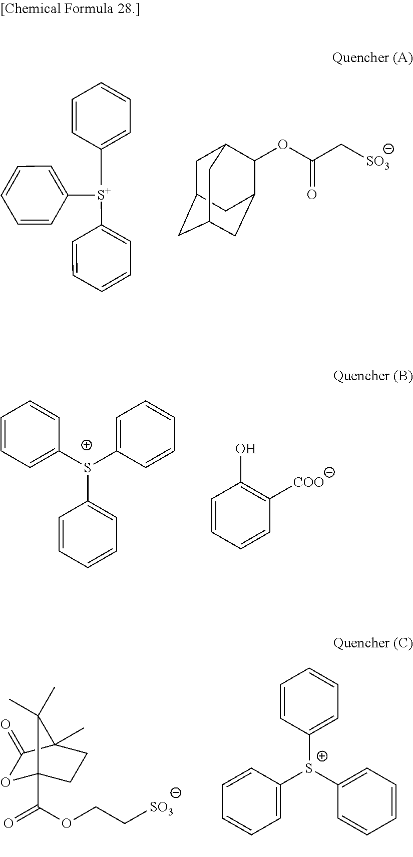

Additive (A): polymer represented by the following formula

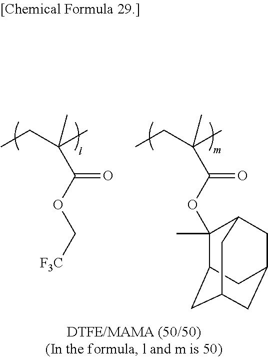

PGMEA: propylene glycol monomethyl ether acetate

PGME: propylene glycol monomethyl ether

<Formation of Solvent Development Negative-Tone Resist Pattern; Examples 1 to 6, Comparative Examples 1 to 4>

An organic anti-reflection film composition (product name: ARC95, manufactured by Brewer Science Ltd.) was applied to an 12-inch silicon wafer using a spinner, and the composition was then baked at 205° C. for 60 seconds, thereby forming an organic anti-reflection film having a film thickness of 90 nm.

Then, the resist composition shown in Tables 2 and 3 was applied to the film using a spinner, and was then subjected to post-applied bake (PAB) on a hotplate at a bake temperature of 110° C. for 60 seconds and dried, thereby forming a resist film having a film thickness of 85 nm.

Subsequently, the resist film was selectively irradiated with an ArF excimer laser (193 nm) through a phase shift mask (PSM), using an exposure apparatus NSR-S609B (manufactured by Nikon Corporation, NA (numerical aperture)=1.30, Crosspole, immersion medium: water).

Thereafter, post-exposure bake (PEB) treatment was conducted at 90° C. for 60 seconds.

Then, solvent development was conducted at 23° C. for 13 seconds using butyl acetate, followed by drying by shaking.

As a result, in each of the examples, a contact hole pattern (hereafter, referred to as “CH pattern”) in which holes having a hole diameter of 45 nm are equally spaced (pitch: 90 nm) was formed.

<Formation of Solvent Development Negative-Tone Resist Pattern (1); Examples 7 to 10, Comparative Examples 5 and 6>

An organic anti-reflection film composition (product name: ARC95, manufactured by Brewer Science Ltd.) was applied to an 12-inch silicon wafer using a spinner, and the composition was then baked at 205° C. for 60 seconds, thereby forming an organic anti-reflection film having a film thickness of 90 nm.

Then, the resist composition shown in Tables 2 and 3 was applied to the film using a spinner, and was then subjected to post-applied bake (PAB) on a hotplate at a bake temperature of 110° C. for 60 seconds and dried, thereby forming a resist film having a film thickness of 85 nm.

Subsequently, the resist film was selectively irradiated with an ArF excimer laser (193 nm) through a mask, using an immersion lithography ArF exposure apparatus NSR-S609B (manufactured by Nikon Corporation; NA (numerical aperture)=1.30; Dipole (in/out=0.78/0.97) with POLANO; immersion medium: water).

Thereafter, post-exposure bake (PEB) treatment was conducted at 95° C. for 60 seconds.

Then, solvent development was conducted at 23° C. for 30 seconds using butyl acetate, followed by drying by shaking.

As a result, in each of the examples, a line and space pattern (hereafter, sometimes referred to simply as “LS pattern”) having a space width of 45 nm and a pitch of 96 nm.

<Formation of Alkali Development Positive-Tone Resist Pattern; Examples 11 and 12, Comparative Examples 7 and 8>

An organic anti-reflection film composition (product name: ARC95, manufactured by Brewer Science Ltd.) was applied to an 12-inch silicon wafer using a spinner, and the composition was then baked at 205° C. for 60 seconds and dried, thereby forming an organic anti-reflection film having a film thickness of 90 nm.

Then, the resist composition shown in Tables 2 and 3 was applied to the film using a spinner, and was then subjected to post-applied bake (PAB) on a hotplate at a bake temperature of 110° C. for 60 seconds and dried, thereby forming a resist film having a film thickness of 90 nm.

Subsequently, the resist film was selectively irradiated with an ArF excimer laser (193 nm) through a phase shift mask, using an immersion exposure apparatus NSR-S609B (manufactured by Nikon Corporation, NA (numerical aperture)=1.07, 1.30, Dipole, 0.78/0.97 w/o P).

Subsequently, an alkali developing treatment was conducted for 13 seconds using a 2.38% by weight tetramethylammonium hydroxide (TMAH).

Thereafter, a post exposure bake treatment was conducted at 95° C. (PEB ° C.) for 60 seconds.

As a result, the following contact hole pattern was formed.

CH pattern: mask size 60 nm/110 nm pitch/hole diameter 55 nm

<Evaluation of Resist Pattern>

[Evaluation of In-Plane Uniformity (CDU) of Pattern Size]

With respect to each CH pattern obtained above, 100 holes in the CH pattern were observed from the upper side thereof using a measuring scanning electron microscope (SEM) (product name: S-9380, manufactured by Hitachi High-Technologies Corporation; acceleration voltage: 300V), and the hole diameter (nm) of each hole was measured. From the results, the value of 3 times the standard deviation σ (i.e., 3σ) was determined. The results are indicated under “CDU” in Tables 4 and 5.

The smaller the thus determined 3σ value is, the higher the level of the dimension uniformity (CD uniformity) of the plurality of holes formed in the resist film.

TABLE 4

| Negative-tone | |
|---|---|
| development | CDU |
| Example 1 | 4.73 |
| Example 2 | 4.92 |
| Example 3 | 4.65 |
| Example 4 | 4.82 |
| Example 5 | 4.52 |
| Example 6 | 4.75 |
| Comparative Example 1 | 5.75 |
| Comparative Example 2 | 6.21 |
| Comparative Example 3 | 5.8 |
| Comparative Example 4 | 6.5 |

As seen from the results shown in Table 4, in Examples 1 to 6, the values of CDU was small, as compared to Comparative Examples 1 to 4. Thus, it was confirmed that, in Examples 1 to 6, the in-plane uniformity of the pattern size was high.

TABLE 5

| Positive-tone | |
|---|---|
| development | CDU |
| Example 11 | 6.9 |
| Example 12 | 6.8 |
| Comparative Example 7 | 8.5 |
| Comparative Example 8 | 8.1 |

As seen from the results shown in Table 5, in Examples 11 and 12, the values of CDU was small, as compared to Comparative Examples 7 and 8. Thus, it was confirmed that, in Examples 11 and 12, the in-plane uniformity of the pattern size was high.

[Evaluation of Line Width Roughness (LWR)]

With respect to each of the LS patterns formed in the manner as described above, the space width at 400 points in the lengthwise direction of the space were measured using a lengthwise measuring scanning electron microscope (SEM) (acceleration voltage: 300V). As the lengthwise measuring scanning electron microscope, a scanning electron microscope manufactured by Hitachi High-Technologies Corporation (product name: S-9380) was used.

From the measurement results of the space widths of each pattern, the value of 3 times the standard deviation s (i.e., 3s) was determined, and the average of the 3s values at 400 points was calculated as a yardstick of LWR. The results are indicated under “LWR (nm)” in Table 6.

The smaller the thus determined 3s value is, the lower the level of roughness of the space portion, indicating that an LS pattern having spaces with a uniform width was obtained.

TABLE 6

| Negative-tone | |
|---|---|
| development | LWR |
| Example 7 | 3.8 |
| Example 8 | 4.1 |
| Example 9 | 4 |
| Example 10 | 4.1 |
| Comparative Example 5 | 4.8 |
| Comparative Example 6 | 6 |

As seen from the examples shown in the table, in Example 7 to 10, the values of LWR were small, as compared to Comparative Examples 5 and 6. Thus, it was confirmed that, in Examples 7 to 10, a pattern having reduced roughness and good shape could be formed.

Further, from the results shown above, a resist pattern formed using the resist composition of the present invention including both the component (A) containing a polymer having a structural unit represented by general formula (1) and the acid-generator component (B) having an anion represented by general formula (2) were excellent in both the CDU and LWR.

<Formation of Solvent Development Negative-Tone Resist Pattern; Example 13>

An organic anti-reflection film composition (product name: ARC95, manufactured by Brewer Science Ltd.) was applied to an 12-inch silicon wafer using a spinner, and the composition was then baked at 205° C. for 60 seconds, thereby forming an organic anti-reflection film having a film thickness of 90 nm.

Then, the resist composition of Example 13 shown in Table 2 was applied to the film using a spinner, and was then subjected to post-applied bake (PAB) on a hotplate at a bake temperature of 110° C. for 60 seconds and dried, thereby forming a resist film having a film thickness of 85 nm.

Subsequently, the resist film was selectively irradiated with an ArF excimer laser (193 nm) through a phase shift mask (PSM), using an exposure apparatus NSR-S610C (manufactured by Nikon Corporation, NA (numerical aperture)=1.30, Crosspole, immersion medium: water).

Thereafter, post-exposure bake (PEB) treatment was conducted at 90° C. for 60 seconds.

Then, solvent development was conducted at 23° C. for 30 seconds using butyl acetate, followed by drying by shaking.

As a result, a contact hole pattern (hereafter, referred to as “CH pattern”) in which holes having a hole diameter of 45 nm are equally spaced (pitch: 90 nm) was formed.

<Evaluation of Resist Pattern>

[Evaluation of In-Plane Uniformity (CDU) of Pattern Size]

With respect to each CH pattern obtained above, 200 holes in the CH pattern were observed from the upper side thereof using a measuring scanning electron microscope (SEM) (product name: CG5000, manufactured by Hitachi High-Technologies Corporation; acceleration voltage: 500V), and the hole diameter (nm) of each hole was measured. From the results, the value of 3 times the standard deviation σ (i.e., 3σ) was determined. The results are indicated under “CDU” in Table 7.

The smaller the thus determined 3σ value is, the higher the level of the dimension uniformity (CD uniformity) of the plurality of holes formed in the resist film.

TABLE 7

| Negative-tone | |
|---|---|
| development | CDU |
| Example 13 | 4.48 |

As seen from the results shown in Table 7, in Example 13, the value of CDU was small. Thus, it was confirmed that, in Example 13, the in-plane uniformity of the pattern size was high.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A resist composition comprising a base component (A) which exhibits changed solubility in a developing solution under action of acid and an acid-generator component (B) which generates acid upon exposure,
the base component (A) comprising a polymer having a structural unit represented by general formula (1) shown below, and
the acid-generator component (B) having an anion represented by general formula (2) shown below: 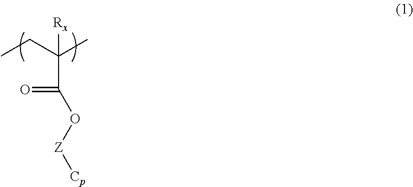
wherein Rₓ represents a hydrogen atom, an alkyl group having 1 to 5 carbon atoms or a halogenated alkyl group having 1 to 5 carbon atoms; Z represents a single bond or an alkyl group having 1 to 5 carbon atoms; Cₚ is a group represented by general formula (Cp-1) shown below: 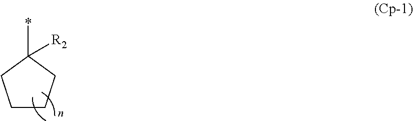
wherein represents a tertiary alkyl group; n represents a positive integer; and * indicates the bonding position with Z;
R_{y}-A-L-(CX₂)ₙ—CF₂—SO₃⁻ (2)
wherein R_{y} represents a cyclic hydrocarbon group of 3 to 20 carbon atoms which may have a hetero atom; A represents —O(C═O)— or —(C═O)O—; L represents a single bond or a divalent hydrocarbon group containing a hetero atom, provided that a hydrogen atom of the divalent hydrocarbon group containing a hetero atom may be substituted with a substituent; each X independently represents H or F; and n represents an integer of 0 to 10.

2. The resist composition according to claim 1, wherein the anion represented by general formula (2) is an anion represented by general formula (2-1) shown below:
R_{z}—OC(═O)—CF₂—SO₃⁻ (2-1)
wherein R_{z} represents a lactone-containing cyclic group.

3. The resist composition according to claim 1, wherein the anion represented by general formula (2) is an anion represented by general formula (2-2) shown below:
R_{w}—C(═O)O-L-(CX₂)ₙ—CF₂—SO₃⁻ (2-2)
wherein R_{w} represents a polycycloalkyl group; L represents a single bond or a divalent hydrocarbon group containing a hetero atom, provided that a hydrogen atom of the divalent hydrocarbon group containing a hetero atom may be substituted with a substituent; each X independently represents H or F; and n represents an integer of 0 to 10.

4. The resist composition according to claim 1, which comprises at least one component selected from the group consisting of a diffusion control agent, an additive, and a solvent.

5. A method of forming a resist pattern, comprising:
forming a resist film on a substrate using the resist composition according to claim 1,
exposing the resist film, and
developing the exposed resist film to form a resist pattern.

6. The resist composition according to claim 3, wherein the anion represented by general formula (2-2) is an anion represented by general formula (2-2-1) or (2-2-2) shown below:
R_{w}—C(═O)O—CH₂—CF₂—SO₃⁻ (2-2-1)
R_{w}—C(═O)O—(CH₂)ₙ—CHF—CF₂—SO₃⁻ (2-2-2)
wherein R_{w} represents a polycycloalkyl group.
